(19) United States
(12) Patent Application Publication
(10) Pub. No.: US 2024/0411965 A1
(43) Pub. Date: Dec. 12, 2024

(54) MODEL GENERATION METHOD, DATA COLLECTION METHOD, AND NON-TRANSITORY STORAGE MEDIUM

(71) Applicant: TOYOTA JIDOSHA KABUSHIKI KAISHA, Aichi-ken (JP)

(72) Inventors: Yuki TAKAHASHI, Miyoshi-shi (JP); Ryo HASHIMOTO, Tokyo-to (JP)

(21) Appl. No.: 18/733,859

(22) Filed: Jun. 5, 2024

(30) Foreign Application Priority Data
Jun. 9, 2023 (JP) 2023-095654

(51) Int. Cl. G06F 30/27

(52) U.S. Cl. CPC G06F 30/27

(57) ABSTRACT

A model generation method according to one aspect of the present disclosure includes a computer acquiring a plurality of data sets each including a combination of training data and correct answer data and performing machine learning of a control model using the acquired plurality of data sets. Using the plurality of data sets includes preferentially using data sets for which reaction speed with respect to an event of control commands indicated by the correct answer data is evaluated as more appropriate as a result of the reaction speed matching a predetermined condition.

### CROSS REFERENCE TO THE RELATED APPLICATION

This application claims the benefit of Japanese Patent Application No. 2023-095654, filed on Jun. 9, 2023, which is hereby incorporated by reference herein in its entirety.

### BACKGROUND

### Technical Field

The present disclosure relates to a model generation method, a data collection method, and a non-transitory storage medium storing a control program.

### Description of the Related Art

Japanese Patent Laid-Open No. 2019-127207 proposes a driving support device configured to acquire information indicating driving operation and information indicating a driving condition in the driving operation, determine whether or not the driving condition is appropriate for learning on the basis of the acquired information and determine that driving operation in the driving condition determined to be inappropriate is to be excluded from a learning object.

### SUMMARY

An object of the present disclosure is to provide a technique for increasing a probability of obtaining a trained machine learning model that has obtained capability of implementing control of a mobile object at appropriate reaction speed or a technique of controlling the mobile object using the trained machine learning model obtained by this technique.

A model generation method according to a first aspect of the present disclosure is to be executed by a computer. The model generation method includes acquiring a plurality of data sets each including a combination of training data indicating environments in which a mobile object moves in chronological order and correct answer data indicating control commands for the mobile object in the environments in chronological order, and performing machine learning of a control model using the acquired plurality of data sets. Performing the machine learning includes training the control model so that a result of deriving a control command of the mobile object from the training data using the control model matches the correct answer data for each of the data sets. Further, using the plurality of data sets includes preferentially using data sets for which reaction speed with respect to an event of the control commands indicated by the correct answer data is evaluated as more appropriate as a result of the reaction speed matching a predetermined condition. The control model may be constituted with a neural network.

A data collection method according to a second aspect of the present disclosure is to be executed by a computer. The data collection method includes collecting a plurality of data sets each including a combination of training data indicating environments in which a mobile object moves in chronological order and correct answer data indicating control commands for the mobile object in the environments in chronological order and outputting the collected plurality of data sets so as to be used in machine learning. Further, collecting the plurality of data sets includes preferentially collecting data sets for which reaction speed with respect to an event of the control commands indicated by the correct answer data is evaluated as more appropriate as a result of the reaction speed matching a predetermined condition.

A control program according to a third aspect of the present disclosure is a program for causing a computer to execute acquiring target data indicating environments in which a target mobile object moves, deriving a control command from the acquired target data using a trained control model, and controlling operation of the target mobile object in accordance with a result of deriving the control command. The trained control model is generated by performing machine learning using a plurality of data sets each including a combination of training data indicating environments in which a mobile object for training moves in chronological order and correct answer data indicating control commands for the mobile object for training in the environments in chronological order. Performing the machine learning includes training the control model so that a result of deriving the control command of the mobile object from the training data using the control model matches the correct answer data for each of the data sets. Further, using the plurality of data sets in the machine learning includes preferentially using in the machine learning, data sets for which reaction speed with respect to an event of the control commands indicated by the correct answer data is evaluated as more appropriate as a result of the reaction speed matching a predetermined condition.

According to the present disclosure, it is possible to provide a technique for increasing a probability of obtaining a trained machine learning model that has obtained capability of implementing control of a mobile object at appropriate reaction speed or a technique of controlling the mobile object using the trained machine learning model obtained by this technique.

### BRIEF DESCRIPTION OF THE DRAWINGS

FIG. 1 schematically illustrates an example of a scene in which the present disclosure is applied;

FIG. 2 schematically illustrates an example of a hardware configuration of a model generation device according to an embodiment;

FIG. 3 schematically illustrates an example of a hardware configuration of a control device according to the embodiment;

FIG. 4 schematically illustrates an example of a software configuration of the model generation device according to the embodiment;

FIG. 5 schematically illustrates an example of a software configuration of the control device according to the embodiment;

FIG. 6 is a flowchart indicating an example of processing procedure regarding machine learning of a control model by the model generation device according to the embodiment;

FIG. 7A schematically illustrates an example of an event according to the embodiment;

FIG. 7B schematically illustrates an example of a method for evaluating reaction speed in the event in FIG. 7A;

FIG. 8A schematically illustrates an example of an event according to the embodiment;

FIG. 8B schematically illustrates an example of a method for evaluating reaction speed in the event in FIG. 8A;

FIG. 9 schematically illustrates an example of an event according to the embodiment;

FIG. 10A schematically illustrates an example of an event according to the embodiment;

FIG. 10B schematically illustrates an example of a method for evaluating reaction speed in the event in FIG. 10A;

FIG. 11A schematically illustrates an example of preferentially using data sets for which reaction speed is evaluated as more appropriate by a predetermined condition in the embodiment;

FIG. 11B schematically illustrates an example of preferentially using data sets for which reaction speed is evaluated as more appropriate by the predetermined condition in the embodiment;

FIG. 12 is a flowchart indicating an example of processing procedure regarding operation control of a mobile object by the control device according to the embodiment;

FIG. 13 schematically illustrates an example of another scene in which the present disclosure is applied;

FIG. 14 schematically illustrates an example of a hardware configuration of a data collection device according to another embodiment;

FIG. 15 schematically illustrates an example of a software configuration of the data collection device according to the other embodiment; and

FIG. 16 is a flowchart indicating an example of processing procedure regarding data collection by the data collection device according to the other embodiment.

### DESCRIPTION OF THE EMBODIMENTS

According to the method proposed by Japanese Patent Laid-Open No. 2019-127207, by excluding driving operation in the driving condition determined to be inappropriate from a learning object, it is expected that an automatic driving model that has obtained capability of executing only appropriate driving operation is generated. However, the present inventors, and the like, have found that the method in related art has the following problems.

In other words, a scene will be assumed where a model is caused to obtain capability of implementing automatic driving of a vehicle through machine learning. In this case, the capability obtained by a trained machine learning model depends on learning data to be used in machine learning. The learning data can be collected from various drivers. In this event, the drivers do not necessarily have constant capability. For example, while some drivers react (execute driving operation) quickly with respect to an event such as deceleration, or the like, of the preceding vehicle, others react slowly with respect to the event. Thus, reaction speed of drivers appearing in the collected learning data can disperse.

Concerning this point, the method in related art merely excludes driving operation determined as inappropriate from the learning object. A difference in the reaction speed can also occur in appropriate driving operation. Thus, with the method in related art, it is not necessarily possible to obtain a trained machine learning model that has obtained capability of implementing automatic driving at appropriate reaction speed.

Note that this problem can arise regardless of types (for example, the number of wheels (such as a two-wheeled vehicle and a four-wheeled vehicle), sizes (such as a large-sized vehicle, a standard-sized vehicle and a small-sized vehicle), a power source (such as an electric vehicle and a fuel vehicle), and the like) of vehicles. Further, such a problem occurs not only in a scene of controlling a vehicle. Movement is also controlled in mobile objects other than vehicles in a similar manner. Thus, a similar problem can arise also in scenes of controlling various mobile objects (such as a flight vehicle (such as a drone) and a ship) other than vehicles.

In contrast, a model generation method according to a first aspect of the present disclosure is to be executed by a computer. The model generation method includes acquiring a plurality of data sets each including a combination of training data indicating environments in which a mobile object moves in chronological order and correct answer data indicating control commands for the mobile object in the environments in chronological order and performing machine learning of a control model using the acquired plurality of data sets. Performing the machine learning includes training the control model so that a result of deriving a control command of the mobile object from the training data using the control model matches the correct answer data for each of the data sets. Further, using the plurality of data sets includes preferentially using data sets for which reaction speed with respect to an event of the control commands indicated by the correct answer data is evaluated as more appropriate as a result of the reaction speed matching a predetermined condition.

Capability of the trained model generated through machine learning depends on data sets to be used in the machine learning. In the first aspect of the present disclosure, data sets for which the reaction speed is evaluated as more appropriate are preferentially used in the machine learning. It is therefore possible to increase a probability of obtaining a trained machine learning model that has obtained capability of implementing control of a mobile object at appropriate reaction speed.

Further, a data collection method according to a second aspect of the present disclosure is to be executed by a computer. The data collection method includes collecting a plurality of data sets each including a combination of training data indicating environments in which a mobile object moves in chronological order and correct answer data indicating control commands for the mobile object in the environments in chronological order and outputting the collected plurality of data sets so as to be used in machine learning. Further, collecting the plurality of data sets includes preferentially collecting data sets for which reaction speed with respect to an event of the control commands indicated by the correct answer data is evaluated as more appropriate as a result of the reaction speed matching a predetermined condition.

In the second aspect of the present disclosure, by preferentially collecting data sets for which the reaction speed is evaluated as more appropriate, it is possible to preferentially use the data sets for which the reaction speed is evaluated as more appropriate in machine learning in a similar manner to the above-described first aspect. It is therefore possible to increase a probability of obtaining a trained machine learning model that has obtained capability of implementing control of a mobile object at appropriate reaction speed.

Further, a control program according to a third aspect of the present disclosure is a program for causing a computer to execute acquiring target data indicating environments in which a target mobile object moves, deriving a control command from the acquired target data using a trained control model, and controlling operation of the target mobile object in accordance with a result of deriving the control command. The trained control model is generated by performing machine learning using a plurality of data sets each including a combination of training data indicating environments in which a mobile object for training moves in chronological order and correct answer data indicating control commands for the mobile object for training in the environments in chronological order. Performing the machine learning includes training the control model so that a result of deriving a control command of the mobile object from the training data using the control model matches the correct answer data for each of the data sets. Further, using the plurality of data sets in the machine learning includes preferentially using in the machine learning, data sets for which reaction speed with respect to an event of the control commands indicated by the correct answer data is evaluated as more appropriate as a result of the reaction speed matching a predetermined condition.

As in the above-described respective aspects, by preferentially using data sets for which the reaction speed is evaluated as more appropriate in machine learning, it is possible to obtain a trained machine learning model that has obtained capability of implementing control of a mobile object at appropriate reaction speed. According to the third aspect of the present disclosure, by using such a trained control model (machine learning model), it can be expected to implement control of the mobile object at appropriate reaction speed.

An embodiment (hereinafter, also expressed as the “present embodiment”) according to one aspect of the present disclosure will be described below on the basis of the drawings. However, the present embodiment described below is merely an example of the present disclosure in all points. Various improvements and modifications may be made without deviating from the scope of the present disclosure. To implement the present disclosure, specific configurations in accordance with the embodiment may be employed as appropriate. Note that while data appearing in the present embodiment is described in natural language, more specifically, the data is indicated with pseudo language, commands, parameters, machine language, and the like, that can be recognized by a computer.

### 1. Application Example

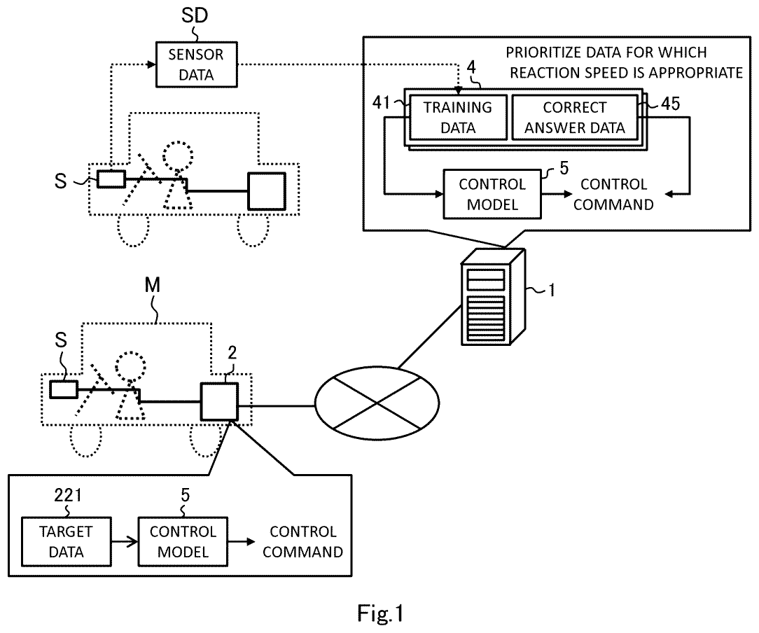

FIG. 1 schematically illustrates an example of a scene in which the present disclosure is applied. A system according to the present embodiment includes a model generation device 1 and a control device 2.

The model generation device 1 according to the present embodiment is one or more computers configured to generate a trained control model 5 by performing machine learning. In the present embodiment, the model generation device 1 acquires a plurality of data sets 4 each including a combination of training data 41 and correct answer data 45. The training data 41 indicates environments in which a mobile object (mobile object for training) moves in chronological order. The correct answer data 45 indicates true values of control commands for the mobile object in the environments indicated by the corresponding training data 41 in chronological order.

The model generation device 1 performs machine learning of the control model 5 using the acquired plurality of data sets 4. Performing this machine learning includes training the control model 5 so that a result of deriving a control command of the mobile object from the training data 41 using the control model 5 matches the corresponding correct answer data 45 for each of the data sets 4. Further, using the plurality of data sets 4 in the machine learning includes preferentially using data sets for which reaction speed with respect to an event of the control commands indicated by the correct answer data 45 is evaluated as more appropriate as a result of the reaction speed matching a predetermined condition. It is possible to generate the trained control model 5 that has obtained capability of deriving a control command in accordance with environments in which the mobile object moves through this machine learning.

On the other hand, the control device 2 according to the present embodiment is one or more computers configured to control movement of a target mobile object M using the trained control model 5. In the present embodiment, the control device 2 acquires target data 221 indicating environments in which the target mobile object M moves. The control device 2 derives a control command from the acquired target data 221 using the trained control model 5. Then, the control device 2 controls operation of the target mobile object M in accordance with a result of deriving the control command.

As described above, in the present embodiment, the trained control model 5 is generated in the model generation device 1 by preferentially using data sets for which reaction speed is evaluated as more appropriate in machine learning. Capability of the trained model generated through machine learning depends on data sets to be used in the machine learning, so that, according to the present embodiment, it can be expected to obtain the trained control model 5 that has obtained capability of implementing control of the mobile object at appropriate reaction speed. Further, in the control device 2 according to the present embodiment, by using such a trained control model 5, it can be expected to implement control of the target mobile object M at appropriate

### (Mobile Object)

If the mobile object can automatically move by machine control, a type of the mobile object (mobile object M) is not particularly limited and may be selected as appropriate in accordance with the embodiment. The mobile object (mobile object M) may be, for example, an arbitrary movable device such as a vehicle, a flight vehicle, a ship, and a robot device. The flight vehicle may be at least one of an uninhabited vehicle such as a drone or a manned aircraft.

In one example, as illustrated in FIG. 1, the mobile object (mobile object M) may be a vehicle. In this case, in the model generation device 1, it can be expected to obtain the trained control model 5 that has obtained capability of implementing control of the vehicle at appropriate reaction speed. Further, in the control device 2, by using such a trained control model 5, it can be expected to implement control of the target vehicle at appropriate reaction speed.

Note that in a case where the mobile object is a vehicle, a type of the vehicle may be arbitrarily selected. The vehicle may be selected from, for example, a two-wheeled vehicle, a three-wheeled vehicle, a four-wheeled vehicle, and the like. A power source of the vehicle may be selected from, for example, electricity, a fuel, and the like. In a case where the vehicle is an automobile, a size of the vehicle may be selected from a large-sized vehicle, a medium-sized vehicle, a quasi-medium-sized vehicle, a standard-sized vehicle, a large-sized special vehicle, a small-sized special vehicle, and the like. In a case where the vehicle is a two-wheeled vehicle, a size of the vehicle may be selected from a large-sized vehicle, a standard-sized vehicle, and the like. As a typical example, the mobile object (mobile object M) may be an automobile having capability of automatic driving at a level equal to or higher than level 2.

### (Environment/Sensor)

The environment is an event observed by at least one of a mobile object itself or surroundings. In one example, at least part of the environment may be observed by one or more sensors S provided inside or outside the mobile object (mobile object M). Correspondingly, each of the training data 41 and the target data 221 includes sensor data SD obtained by one or more sensors S.

If the sensor S can observe an arbitrary environment in which the mobile object moves, a type of the sensor S does not have to be particularly limited and may be selected as appropriate in accordance with the embodiment. In one example, one or more sensors S may include a camera (image sensor), a radar, light detection and ranging (LiDAR), a sonar (ultrasonic sensor), an infrared sensor, a global navigation satellite system (GNSS)/global positioning satellite (GPS) module, and the like.

### (Control Command)

The control command is related to operation of the mobile object. A configuration of the control command may be determined as appropriate in accordance with the embodiment. For example, the control command may include acceleration, deceleration, steering, or a combination thereof. The acceleration and the deceleration may include gear changes. In this case, in the model generation device 1, it can be expected to obtain the trained control model 5 that has obtained capability of implementing control of acceleration, deceleration, steering, or a combination thereof at appropriate reaction speed. Further, in the control device 2, by using such a trained control model 5, it can be expected to implement control of acceleration, deceleration, steering, or a combination thereof at appropriate reaction speed.

In one example, in a case where the mobile object (mobile object M) is a vehicle, the control command may include at least one of acceleration, deceleration, or steering of the vehicle. In a case where the control command includes at least one of acceleration, deceleration, or steering, the control command may be expressed with a path. Correspondingly, the control model 5 may be expressed as a path planner.

Further, the control command may further include a command regarding operation of the mobile object. As one example, in a case where the mobile object (mobile object M) is a vehicle, the control command may include vehicle operation of a directional indicator, hazard lights, a horn, communication processing (such as, for example, transmission of data to a center, issuance of an urgent call), and the like.

### (Data Set)

Each data set 4 may be generated as appropriate. Each data set 4 may be automatically generated by operation of a computer or manually generated by at least partially including operation by an operator. Typically, operation data and environment data on the mobile object may be collected while a subject controls the mobile object wholly through manual operation. The environment data (observation data) may be obtained by the sensor S mounted on the mobile object. The operation data may be obtained by recording manual operation by the subject. Further, the training data 41 of each data set 4 may be generated from the environment data. The correct answer data 45 may be generated from the operation data. In other words, typically, the data sets 4 may be generated from a result of the manual operation (for example, manual driving of the vehicle) by the subject. In a case where the data sets 4 are obtained by utilizing the mobile object, the mobile object for which the data sets 4 are to be obtained may include the mobile object M which is to use the generated trained control model 5 or does not have to include the mobile object M. In other words, the mobile object for training may include the target mobile object M or does not have to include the target mobile object M. The mobile object for training may include a mobile object to be used by an end user. In this case, the end user may be a subject. Further, the mobile object for training may include a mobile object to be used experimentally.

However, a method for generating the data sets 4 does not have to be limited to such an example and may be selected as appropriate in accordance with the embodiment. In another example, in a similar manner to the above-described example, while the data sets 4 may be generated from a result of manual operation by the subject, the manual operation may include operation by the subject during operation of partial automatic control, such as override operation with respect to arbitrary automatic control. In another example, at least one or some of the data sets 4 may be obtained using a virtual method such as simulation. In another example, at least one or some of the data sets 4 may be obtained by a framework of reinforcement learning. Further, in another example, at least one or some of the data sets 4 may be obtained by data augmentation with respect to an arbitrary data set. The data augmentation is performed by generating new training data by changing an attribute value of the training data. For example, in a case where the training data includes an image, change of parameters may be performed by image processing such as parallel movement, enlargement, reduction, rotation and addition of noise on the image. In a case where at least one or some of the data sets 4 is obtained by data augmentation, one or more new data sets may be generated by changing values of attributes other than at least one of reaction speed or attributes depending on the reaction speed for the training data of an arbitrary data set (original data set) and providing correct answer data in accordance with the change. The plurality of data sets 4 may include the generated new data set.

### (Control Model)

The control model 5 includes a machine learning model having one or more arithmetic parameters that are adjustable by machine learning. The one or more arithmetic parameters are used to calculate inference (in the present case, derivation of the control command) to be performed. The machine learning is adjustment (optimization) of values of the arithmetic parameters using learning data (in the present case, a plurality of data sets 4). Each of a configuration and a type of the machine learning model does not have to be particularly limited and may be selected as appropriate in accordance with the embodiment. The machine learning model may include, for example, a neural network, support vector machine, a regression model, a decision tree model, and the like.

As one example, the control model 5 may be constituted with a neural network. A structure of the neural network may be determined as appropriate in accordance with the embodiment. The structure of the neural network may be specified by, for example, the number of layers from an input layer to an output layer, a type of each layer, the number of nodes (neurons) included in each layer, a connection relationship between nodes of each layer, and the like. In one example, the neural network may have a recursive structure. Further, the neural network may include an arbitrary layer such as, for example, a fully-connected layer, a convolutional layer, a pooling layer, a deconvolutional layer, an unpooling layer, a normalization layer, a dropout layer and a long short-term memory (LSTM). The neural network may have an arbitrary mechanism such as an attention mechanism. The control model 5 (neural network) may include an arbitrary model such as a graph neural network (GNN), a diffusion model, and a generation model (such as, for example, a generative adversarial network and a transformer). In a case where the neural network is used in the control model 5, a weight of connection between the nodes included in the control model 5 (neural network) and thresholds of the respective nodes are one example of the arithmetic parameters.

If the control command can be derived from the environment of the mobile object, an input/output form of the control model 5 does not have to be particularly limited and may be selected as appropriate in accordance with the embodiment. For example, the control model 5 may be configured to derive control commands at one or more time point from environment data at one or more time points. Further, the control model 5 may be constituted so as to be able to accept time-series data by its structure. As one example, the control model 5 may be constituted so as to be able to accept time-series data by being constituted in a recursive type. As another example, the control model 5 may be constituted so that the environment data at a plurality of time points is input in bulk. Alternatively, the control model 5 may be constituted so as not to be able to structurally accept time-series data. For example, the control model 5 may be configured to derive a control command at one time point from the environment data at one time point. In this case, the control model 5 may be used to obtain a calculation result with respect to the time-series data by sequentially accepting data at respective time points in the time-series data and sequentially outputting calculation results. Further, the control model 5 may be configured to immediately derive the control command. Alternatively, the control model 5 may be configured to derive control commands at a plurality of future time points in bulk. In this case, at least one or some of the control commands derived in bulk may be used to control the mobile object (mobile object M).

If the control model 5 is involved with at least part of inference processing of deriving a control command from the environment of the mobile object, the content of the processing to be executed by the control model 5 does not have to be particularly limited and may be selected as appropriate in accordance with the embodiment. In one example, the control model 5 may be configured to execute periphery recognition and path planning (route/track planning). The control model 5 may be configured to further execute motion planning (operation/control planning). In other words, the control model 5 may be an end-to-end model.

Further, if operation of the mobile object can be controlled by an output of the control model 5, an output format of the control model 5 may be selected as appropriate in accordance with the embodiment. The control model 5 may be configured to directly output the control command. Alternatively, the control command may be obtained by executing arbitrary information processing (interpretation processing) on the output of the control model 5. The control command may be configured to directly indicate a control amount (a control instruction value, a control output amount) of the mobile object, such as, for example, an accelerator control amount, a brake control amount and a steering wheel angle. Alternatively, the control command may be configured to indirectly indicate the control amount of the mobile object with, for example, a path, a state after control, and the like. In this case, the control amount of the mobile object may be obtained from the control command by executing arbitrary information processing. In one example, in a case where the mobile object is a vehicle, the control amount of the vehicle may be obtained by applying an inference result obtained from the control model 5 to a vehicle model. The vehicle model may have various kinds of parameters of an accelerator, a brake, a steering wheel, and the like, and may be constituted as appropriate so as to derive the control amount from indirect information (such as a path and a state after control).

Note that the correct answer data 45 of each data set 4 may be constituted as appropriate so as to directly or indirectly indicate the control command. In a case where the control command is derived from the output of the control model 5 by executing arbitrary calculation processing, the correct answer data 45 may be provided to the control command derived from the output of the control model 5 (that is, the correct answer data 45 may be configured to directly indicate the control command). Alternatively, the correct answer data 45 may be provided to the output of the control model 5 (in other words, the correct answer data 45 may be configured to indirectly indicate the control command).

### (Event)

The event may include various events that can be involved with operation of the mobile object. Further, the event may include various events that can be detected by the sensor S. Detection by the sensor S means determination by a sensor value. In other words, a start time point of the event may be specified by sensor data. A detection (determination, specification) method may be determined as appropriate in accordance with the event. The sensor data may be analyzed using an arbitrary method, and the start time point of the event may be specified (that is, occurrence of the event may be detected) by the analysis.

Correspondingly, the mobile object (mobile object M) may include the sensor S. The training data 41 may include sensor data SD obtained by the sensor S. Further, the start time point of the event in the training data 41 may be specified by the sensor data SD. The reaction speed in each data set 4 may be mechanically evaluated by the specified start time point, so that it is possible to make determination of the data sets 4 to be preferentially used in machine learning more efficient. In other words, work of selecting the data sets 4 to be preferentially used can be at least partially automated, so that it is possible to achieve reduction in time and effort. Note that the start time point of operation with respect to the event appears in the correct answer data 45. Thus, in this embodiment, the reaction speed (that is, a period from a time point at which the event has occurred until a time point at which operation has been started) with respect to the event can be specified from the training data 41 and the correct answer data 45.

### (Examples of Event)

As one example, in a case where the mobile object (mobile object M) is a vehicle, the event may include at least one of deceleration of a preceding vehicle of the vehicle, cutting-in of a vehicle traveling side by side, occurrence of a parked vehicle, occurrence of an obstacle or change of a traffic light. The obstacle may include any object that may inhibit traveling of the vehicle. The obstacle may be, for example, a pedestrian, a bicycle, or the like. In this case, in the model generation device 1, it can be expected to obtain the trained control model 5 that has obtained capability of implementing control of the vehicle at appropriate reaction speed with respect to at least one of these events. Further, in the control device 2, by using such a trained control model 5, it can be expected to implement control of the target vehicle at appropriate reaction speed with respect to at least one of these events.

Note that in a case where the event for which automatic driving (automatic control) is to be performed includes deceleration of the preceding vehicle, the control command may include a command of deceleration in accordance with the preceding vehicle. In a case where the event for which automatic driving is to be performed includes cutting-in of a vehicle traveling side by side, the control command may include a command of deceleration in accordance with the vehicle traveling side by side. In a case where the event for which automatic driving is to be performed includes occurrence of a parked vehicle, the control command may include at least one of deceleration or steering in accordance with the parked vehicle. In a case where the event for which automatic driving is to be performed includes occurrence of an obstacle, the control command may include at least one of deceleration or steering in accordance with the obstacle. In a case where the event for which automatic driving is to be performed includes change of a traffic light, the control command may include a command of acceleration or deceleration in accordance with the traffic light. These events may be diverted to other kinds of mobile objects (such as, for example, a flight vehicle and a ship).

### (Matching of Predetermined Condition)

A predetermined condition may be specified as appropriate so as to be able to evaluate appropriate reaction speed in accordance with the event. In one example, the predetermined condition may be specified so as to evaluate higher reaction speed as more appropriate. In this case, data sets for which reaction speed with respect to the event is higher (are evaluated as appropriate reaction speed and) may be preferentially used in machine learning. However, the predetermined condition does not have to be limited to such an example. In another example, the predetermined condition may specify a range (an upper limit value and a lower limit value) of appropriate reaction speed. In this case, data sets for which the reaction speed belongs to the range specified by the predetermined condition may be preferentially used in machine learning, and other data sets (that is, data sets for which the reaction speed is higher or lower than the reaction speed in the range specified by the predetermined condition) do not have to be preferentially used in machine learning.

### (Preferential Use)

Preferentially using data sets for which the reaction speed is evaluated as more appropriate may be performed using an arbitrary method of making data sets to be preferentially used more likely to be reflected in training of the control model 5 than data sets not to be preferentially used.

As one example, whether or not to use a data set may be simply determined in accordance with whether or not to prioritize the data set. In other words, preferentially using data sets for which the reaction speed is evaluated as more appropriate may be performed by using data sets for which the reaction speed is evaluated as appropriate in training of the control model 5 and not using data sets for which the reaction speed is not evaluated as appropriate in training of the control model 5. According to this method, it is possible to extremely easily reflect evaluation of the reaction speed in machine learning.

As another example, data sets for which the reaction speed is evaluated as appropriate among the plurality of data sets 4 are made a first data set, and data sets for which the reaction speed is not evaluated as appropriate (that is, does not match the predetermined condition) are made a second data set. Preferentially using data sets for which the reaction speed is evaluated as more appropriate may be performed by making a sampling probability in machine learning of the first data set higher among the plurality of data sets 4 and making a sampling probability in machine learning of the second data set lower than that of the first data set.

In this case, preferentially using data sets for which the reaction speed is evaluated as more appropriate may be performed by further excluding at least part of the second data set from a target of machine learning (that is, making the sampling probability 0). Alternatively, preferentially using data sets for which the reaction speed is evaluated as more appropriate may be performed by further not excluding the second data set from a target of machine learning (that is, not making the sampling probability 0). In an actual scene, there can be a case where operation with slow reaction speed may be executed as appropriate operation due to an external factor. For example, sudden operation such as sudden braking and sudden steering is assumed as operation with slow reaction speed. Further, there is also a possibility that the reaction speed is evaluated as apparently slow because it takes time to perform operation after the event is detected. Concerning this point, the control model 5 can be caused to also learn these kinds of operation by not excluding the second data set from a target of machine learning. It can be therefore expected that robustness of the operation with respect to the event is improved.

As still another example, preferentially using data sets for which the reaction speed is evaluated as more appropriate may be performed by making a weight of training of the first data set greater among the plurality of data sets 4 and making a weight of training of the second data set smaller. For example, making the weight of training greater may be performed by increasing a learning rate, and making the weight of training smaller may be performed by decreasing the learning rate. In other words, preferentially using data sets for which the reaction speed is evaluated as more appropriate may be performed by making an update amount of parameters of the control model 5 in training of one time greater for data sets to be preferentially used. As still another example, preferentially using data sets may include both methods of the sampling probability and the weight.

Note that priority of use may be set as appropriate. In one example, the priority may include two stages (that is, two stages of prioritize/not prioritize). As another example, the priority may be set to three or more stages. In this case, the priority may be different (that is, may be superior or inferior) among data sets to be preferentially used. In a similar manner, the priority may be different among data sets not to be preferentially used.

### (Control of Operation)

In one example, controlling operation of the target mobile object M may be performed by directly controlling the target mobile object M. In another example, the mobile object (mobile object M) may include a dedicated control device such as, for example, a controller. In this case, controlling operation of the target mobile object M by the control device 2 may be performed by indirectly controlling the target mobile object M by providing a derivation result to the dedicated control device.

### (System Configuration)

In one example, as illustrated in FIG. 1, the model generation device 1 and the control device 2 may be configured to be able to perform communication (connection) with each other via a network. A type of the network does not have to be particularly limited and may be selected as appropriate from, for example, the Internet, a wireless communication network, a mobile communication network, a telephone network, a leased line, and the like. However, a method in which data is exchanged between the model generation device 1 and the control device 2 does not have to be limited to such an example and may be selected as appropriate in accordance with the embodiment. In another example, data may be exchanged by utilizing a storage medium.

Further, in the example in FIG. 1, the model generation device 1 and the control device 2 are different computers. However, the system configuration does not have to be limited to such an example. In another example, the model generation device 1 and the control device 2 may be constituted with an integrated computer. Further, at least one of the model generation device 1 or the control device 2 may be constituted with a plurality of computers.

Further, in the example in FIG. 1, the control device 2 is mounted inside the mobile object M. However, arrangement of the control device 2 does not have to be limited to such an example. The control device 2 may be disposed outside the mobile object M if the control device 2 can directly or indirectly control operation of the mobile object M.

### 2. Configuration Example

### [Hardware Configuration Example]

### <Model Generation Device>

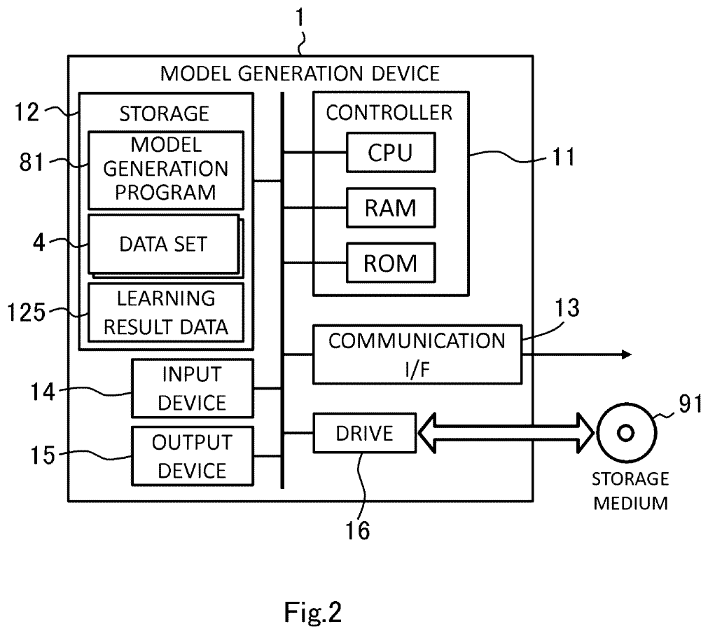

FIG. 2 schematically illustrates an example of a hardware configuration of the model generation device 1 according to the present embodiment. As illustrated in FIG. 2, the model generation device 1 according to the present embodiment is a computer to which a controller 11, a storage 12, a communication interface 13, an input device 14, an output device 15, and a drive 16 are electrically connected.

The controller 11, which includes a central processing unit (CPU) that is a hardware processor, a random access memory (RAM), a read only memory (ROM), and the like, is configured to execute information processing on the basis of a program and various kinds of data. The controller 11 (CPU) is one example of processor resources.

The storage 12 may be constituted with, for example, a hard disk drive, a solid state drive, or the like. The storage 12 (and the RAM, the ROM) is one example of memory resources. In the present embodiment, the storage 12 stores various kinds of information such as a model generation program 81, a plurality of data sets 4, and learning result data 125.

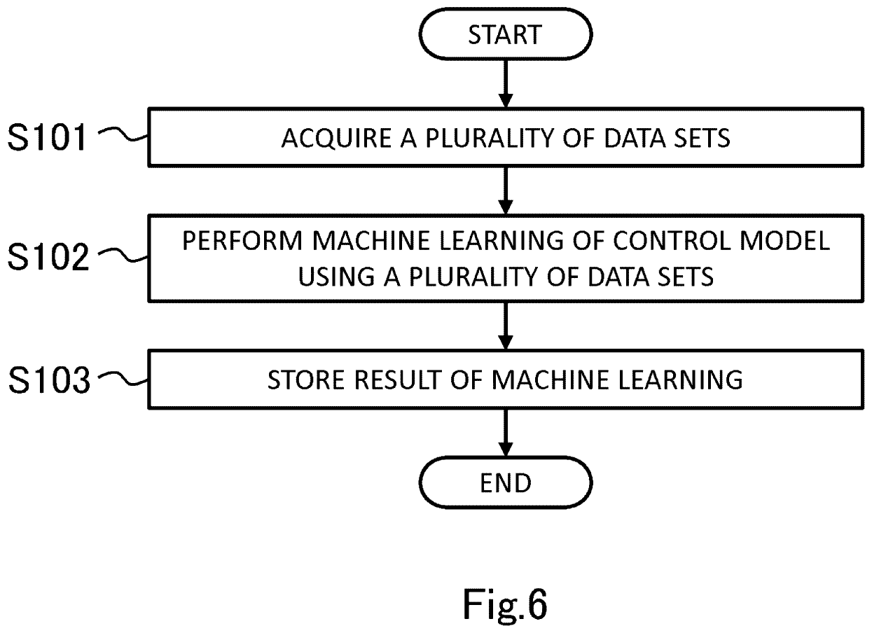

The model generation program 81 is a program for causing the model generation device 1 to execute information processing (FIG. 6 which will be described later) regarding machine learning of the control model 5. The model generation program 81 includes a series of commands of the information processing. The learning result data 125 indicates information regarding the generated trained control model 5. In the present embodiment, the learning result data 125 is generated as a result of executing the model generation program 81.

The communication interface 13 is an interface for performing wired or wireless communication via a network. The communication interface 13 may be constituted with, for example, a wired local area network (LAN) module, a wireless LAN module, and the like. The model generation device 1 may execute data communication with other computers (for example, the control device 2) via the communication interface 13.

The input device 14 is a device for performing input such as, for example, a mouse and a keyboard. The output device 15 is a device for performing output such as, for example, a display and a speaker. The operator can operate the model generation device 1 by utilizing the input device 14 and the output device 15. The input device 14 and the output device 15 may be integrally constituted by, for example, a touch panel display, or the like.

The drive 16 is a device for loading various kinds of information such as a program stored in the storage medium 91. At least one of the above-described model generation program 81, the plurality of data sets 4 or the learning result data 125 may be stored in the storage medium 91 in place of the storage 12 or in addition to the storage 12. The storage medium 91 is configured to accumulate various kinds of information (such as the stored program) using electrical, magnetic, optical, mechanical or chemical reaction so that machine such as a computer can read the information. The model generation device 1 may acquire at least one of the model generation program 81 or the plurality of data sets 4 from the storage medium 91.

Here, FIG. 2 illustrates a disk-type storage medium such as a CD and a DVD as one example of the storage medium 91. However, a type of the storage medium 91 does not have to be limited to a disk type. Examples of a storage medium other than a disk type can include, for example, a semiconductor memory such as a flash memory. A type of the drive 16 may be selected as appropriate in accordance with the type of the storage medium 91.

Note that concerning a specific hardware configuration of the model generation device 1, components can be omitted, replaced and added as appropriate in accordance with the embodiment. For example, the controller 11 may include a plurality of hardware processors. The hardware processors may include a microprocessor, a field-programmable gate array (FPGA), a digital signal processor (DSP), an electronic control unit (ECU), a graphics processing unit (GPU), and the like. At least one of the communication interface 13, the input device 14, the output device 15, or the drive 16 may be omitted. The model generation device 1 may be constituted with a plurality of computers. In this case, hardware configurations of the respective computers may be the same or do not have to be the same. The model generation device 1 may be a general-purpose server device, a general-purpose personal computer (PC), an industrial PC, a terminal device (such as, for example, a tablet PC), or the like, other than a computer designed exclusively for a service to be provided.

### <Control Device>

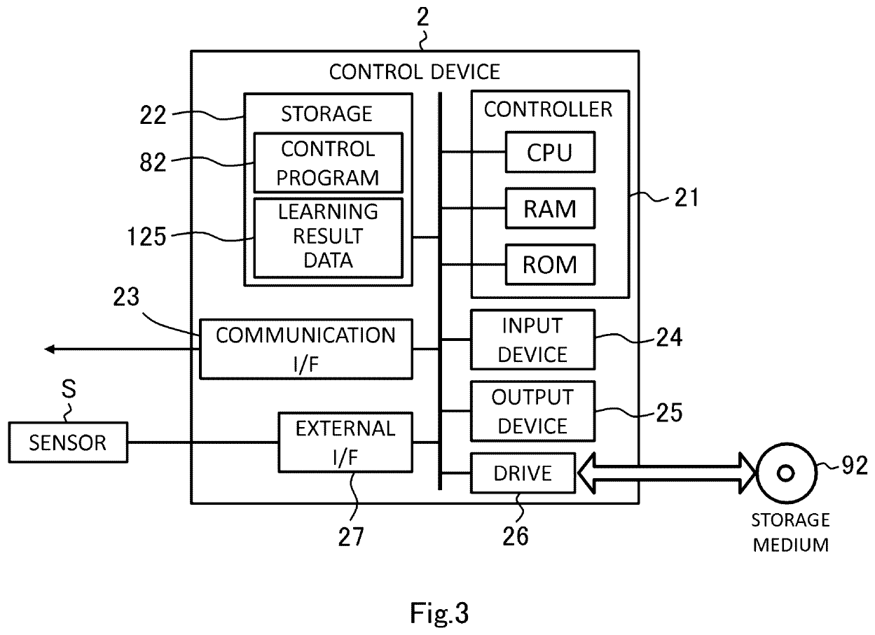

FIG. 3 schematically illustrates an example of a hardware configuration of the control device 2 according to the present embodiment. As illustrated in FIG. 3, the control device 2 according to the present embodiment is a computer to which a controller 21, a storage 22, a communication interface 23, an input device 24, an output device 25, a drive 26 and an external interface 27 are electrically connected.

The controller 21 to the drive 26 of the control device 2 and the storage medium 92 may be respectively constituted in a similar manner to the controller 11 to the drive 16 of the model generation device 1 and the storage medium 91. The controller 21 (CPU) is one example of processor resources of the control device 2, and the storage 22 (and the RAM, the ROM) is one example of memory resources of the control device 2. In the present embodiment, the storage 22 stores various kinds of information such as a control program 82 and the learning result data 125.

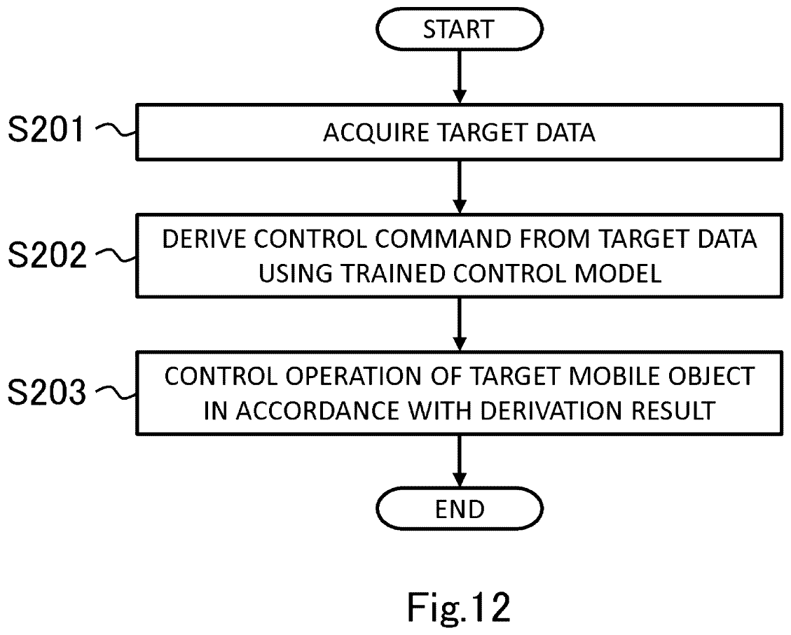

The control program 82 is a program for causing the control device 2 to execute information processing (FIG. 12 which will be described later) regarding automatic control of the target mobile object M by the trained control model 5. The control program 82 includes a series of commands of the information processing. At least one of the control program 82 or the learning result data 125 may be stored in the storage medium 92 in place of the storage 22 or in addition to the storage 22. The control device 2 may acquire at least one of the control program 82 or the learning result data 125 from the storage medium 92.

The control device 2 may perform data communication with other computers (for example, the model generation device 1) via the communication interface 23. The operator can operate the control device 2 by utilizing the input device 24 and the output device 25. The input device 24 and the output device 25 may be integrally constituted by, for example, a touch panel display, or the like.

The external interface 27 is an interface for connecting to an external device. The external interface 27 may be, for example, a universal serial bus (USB) port, a dedicated port, or the like. A type and the number of external interface 27 may be determined as appropriate in accordance with types and the number of external devices to be connected. In the present embodiment, the control device 2 may be connected to the sensor S via the external interface 27. At least part of the target data 221 may be constituted with sensor data obtained by the sensor S. Note that a connection method of the sensor S does not have to be limited to such an example. In another example, the sensor S may be connected via the communication interface 23.

Note that concerning a specific hardware configuration of the control device 2, components can be omitted, replaced and added as appropriate in accordance with the embodiment. For example, the controller 21 may include a plurality of hardware processors. The hardware processors may include a microprocessor, an FPGA, a DSP, an ECU, a GPU, and the like. At least one of the communication interface 23, the input device 24, the output device 25, the drive 26, or the external interface 27 may be omitted. The control device 2 may be constituted with a plurality of computers. In this case, hardware configurations of the respective computers may be the same or do not have to be the same. The control device 2 may be a general-purpose computer, a mobile phone including a smartphone, a tablet personal computer (PC), or the like, other than a computer exclusively designed for a service to be provided. In a case where the mobile object M is a vehicle, the control device 2 may be an in-vehicle device.

### [Software Configuration Example]

### <Model Generation Device>

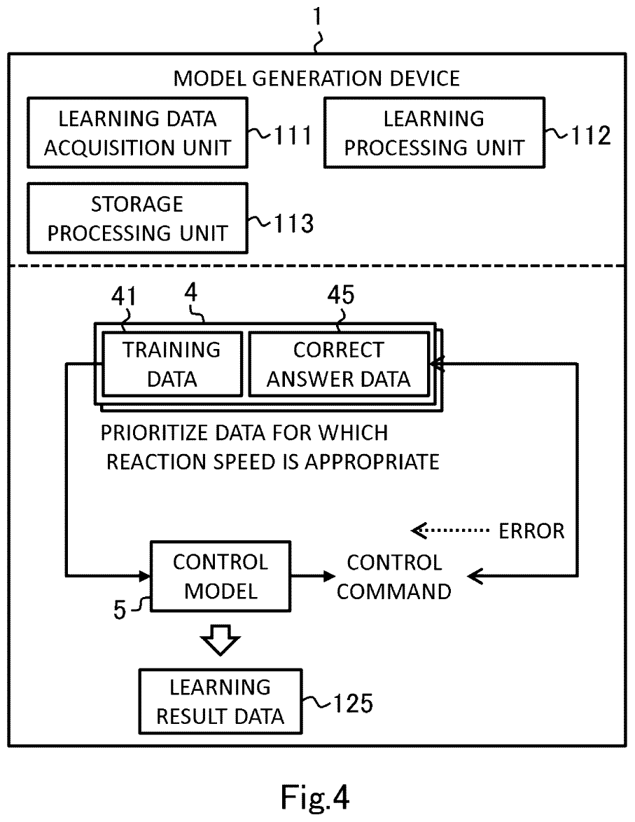

FIG. 4 schematically illustrates an example of a software configuration of the model generation device 1 according to the present embodiment. The controller 11 of the model generation device 1 loads the model generation program 81 stored in the storage 12 to the RAM and executes a command included in the model generation program 81 by the CPU. By this means, the model generation device 1 operates as a computer including a learning data acquisition unit 111, a learning processing unit 112 and a storage processing unit 113 as software modules. In other words, in the present embodiment, each software module of the model generation device 1 is implemented by the controller 11 (CPU).

The learning data acquisition unit 111 is configured to acquire a plurality of data sets 4 each including a combination of the training data 41 and the correct answer data 45. The learning processing unit 112 is configured to perform machine learning of the control model 5 using the acquired plurality of data sets 4. In the present embodiment, performing machine learning includes training the control model 5 so that a result of deriving a control command of the mobile object from the training data 41 using the control model 5 matches the corresponding correct answer data 45 for each of the data sets 4. Further, in the machine learning, using the plurality of data sets 4 includes preferentially using data sets for which reaction speed with respect to an event of control commands indicated by the correct answer data 45 is evaluated as more appropriate as a result of the reaction speed matching a predetermined condition. The trained control model 5 is generated by execution of this machine learning.

The storage processing unit 113 is configured to store the trained control model 5 generated by machine learning. In one example, the storage processing unit 113 may be configured to generate the learning result data 125 indicating the trained control model 5 generated as a result of machine learning. If information for executing calculation processing of the trained control model 5 can be held, a configuration of the learning result data 125 does not have to be particularly limited and may be determined as appropriate in accordance with the embodiment. As one example, the learning result data 125 may include information indicating values of arithmetic parameters adjusted by machine learning. The learning result data 125 may include information indicating a configuration (such as, for example, a structure of a neural network) of the trained control model 5 according to circumstances. The storage processing unit 113 may be configured to store the generated learning result data 125 in a predetermined memory area. The learning result data 125 may be provided to the control device 2 at an arbitrary timing.

### <Control Device>

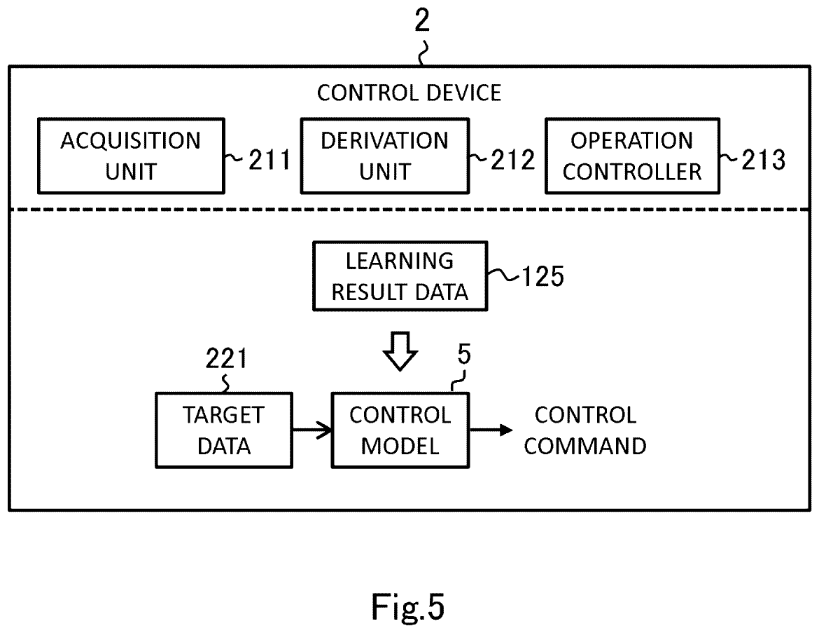

FIG. 5 schematically illustrates an example of a software configuration of the control device 2 according to the present embodiment. The controller 21 of the control device 2 loads the control program 82 stored in the storage 22 to the RAM and executes a command included in the control program 82 by the CPU. By this means, as illustrated in FIG. 5, the control device 2 according to the present embodiment operates as a computer including an acquisition unit 211, a derivation unit 212 and an operation controller 213 as software modules. In other words, in the present embodiment, in a similar manner to the model generation device 1, each software module of the control device 2 is also implemented by the controller 21 (CPU).

The acquisition unit 211 is configured to acquire the target data 221 indicating environments in which the target mobile object M moves. The derivation unit 212 includes the trained control model 5 generated by the above-described model generation device 1 by holding the learning result data 125. The derivation unit 212 is configured to derive a control command from the acquired target data 221 using the trained control model 5. The operation controller 213 is configured to control operation of the target mobile object M in accordance with a result of deriving the control command (that is, a control command derived using the trained control model 5).

### <Others>

In the present embodiment, an example has been described where each software module of the model generation device 1 and the control device 2 is implemented by a general-purpose CPU. However, one, some, or all of the software modules may be implemented by one or more dedicated processors. The above-described modules may be implemented as hardware modules.

Concerning software configurations of the model generation device 1 and the control device 2, modules may be omitted, replaced and added as appropriate in accordance with the embodiment.

### 3. Operation Example

### [Model Generation Device]

FIG. 6 is a flowchart indicating an example of processing procedure regarding machine learning of the control model 5 by the model generation device 1 according to the present embodiment. The following processing procedure is one example of a model generation method to be executed by a computer. However, the following processing procedure of the model generation device 1 is merely one example, and each step may be changed as far as possible. Further, concerning the following processing procedure, steps may be omitted, replaced and added as appropriate in accordance with the embodiment.

### <Step S101>

In step S101, the controller 11 operates as the learning data acquisition unit 111. In other words, the controller 11 acquires a plurality of data sets 4 each including a combination of the training data 41 and the correct answer data 45.

The training data 41 indicates environments in which the mobile object moves in chronological order. In one example, the training data 41 may include the sensor data SD obtained by the sensor S. In addition, the training data 41 may include arbitrary information that can be involved with control such as, for example, set speed, speed limit, map information and navigation information. The correct answer data 45 directly or indirectly indicates control commands for the mobile object in the environments indicated by the corresponding training data 41 in chronological order.

As described above, the respective data sets 4 may be generated (collected) as appropriate. The generated data sets 4 may be stored in the model generation device 1 (at least one of the storage 12 or the storage medium 91). Alternatively, the respective data sets 4 may be stored in other computers such as a network server (for example, a network attached storage (NAS)). In this case, when machine learning is performed, the controller 21 may acquire each data set 4 via a network, an external main memory, the storage medium 91, or the like. Each data set 4 may be stored in a database format.

At least one or some of the plurality of data sets 4 may be generated by the model generation device 1. At least one or some of the plurality of data sets 4 may be generated by computers other than the model generation device 1. In a case where the data sets 4 are generated by other computers, the controller 11 may acquire the data sets 4 generated by other computers via a network, an external main memory, the storage medium 91, or the like.

The number of the data sets 4 to be acquired may be determined as appropriate in accordance with the embodiment. If the plurality of data sets 4 are acquired, the processing of the controller 11 proceeds to the next step S102.

### <Step S102>

In step S102, the controller 11 operates as the learning processing unit 112. In other words, the controller 11 performs machine learning of the control model 5 using the acquired plurality of data sets 4. In the machine learning, the controller 11 trains the control model 5 so that a result of deriving a control command of the mobile object from the training data 41 using the control model 5 matches the corresponding correct answer data 45 for each of the data sets 4.

The control model 5 (machine learning model) includes one or more arithmetic parameters for executing calculation processing of solving an inference task. Training the control model 5 means optimization (adjustment) of values of the arithmetic parameters of the control model 5 (machine learning model) in accordance with the provided learning data (plurality of data sets 4). A method of machine learning may be determined as appropriate in accordance with the embodiment such as a type and a structure of the machine learning model to be used as the control model 5. As a method for adjusting the arithmetic parameters, an arbitrary method such as, for example, an error backpropagation method and solving an optimization problem may be employed.

### (One Example of Machine Learning Method)

As a typical example, in a case where the control model 5 is constituted with a neural network, the controller 11 first prepares the control model 5 to be subjected to processing of machine learning. A structure of the control model 5 to be prepared, an initial value of a weight of connection between respective neurons, and an initial value of a threshold of each neuron may be provided by a template or may be provided by an input of the operator. In a case where relearning is performed, the controller 11 may prepare the control model 5 on the basis of the learning result data obtained by performing machine learning of the past. Then, the controller 11 executes learning processing (supervised learning) of the control model 5 by utilizing the training data 41 of each data set 4 as input data and utilizing the correct answer data 45 as a teaching signal (label).

As illustrated in FIG. 4, as one example of the learning processing, in the first step, the controller 11 inputs the training data 41 of each data set 4 and executes calculation processing of forward propagation of the control model 5. As a result of this calculation processing, the controller 11 acquires an output value corresponding to an inference result (direct or indirect derivation result of the control command) with respect to the training data 41 from the control model 5. In the second step, the controller 11 calculates an error between the acquired output value and the corresponding correct answer data 45. In the third step, the controller 11 calculates a gradient of the calculated error. Then, the controller 11 calculates errors of values of the arithmetic parameters (such as a weight of connection between the nodes and a threshold of each node) of the control model 5 by backpropagating the calculated gradient of the error using an error backpropagation method. In the fourth step, the controller 11 updates the values of the arithmetic parameters on the basis of the calculated errors. A degree of updating the values of the arithmetic parameters may be adjusted in accordance with a learning rate.

The controller 11 adjusts the values of the arithmetic parameters of the control model 5 by repeating the first to the fourth steps described above so that a sum of errors between the output values output from the control model 5 and the correct answer data 45 becomes small for each of the data sets 4. This adjustment of the values of the arithmetic parameters may be repeated until a predetermined condition is satisfied, for example, until adjustment is executed a set number of times of iterations or until a sum of the calculated errors becomes equal to or less than a threshold. The threshold may be set as appropriate in accordance with the embodiment. Further, machine learning conditions such as an objective function (a cost function, a loss function, an error function) for calculating an error, a learning rate and optimization algorithm may be set as appropriate in accordance with the embodiment.

The adjustment of the values of the arithmetic parameters of the control model 5 may be executed on a mini batch. As one example, before the processing from the first to the fourth steps described above is executed, the controller 11 may generate a mini batch by extracting arbitrary samples (data sets) from a plurality of data sets 4. A size of the mini batch may be set as appropriate in accordance with the embodiment. Further, the controller 11 may execute the processing from the first to the fourth steps described above on the data sets 4 included in the generated mini batch. In a case where the first to the fourth steps are repeated, the controller 11 may generate a mini batch again and may execute the processing from the first to the fourth steps described above on the generated new mini batch.

Note that the machine learning method does not have to be limited to such an example of supervised learning, and other methods may be at least partially employed. As another example, deep reinforcement learning may be employed. In this case, one or some of the plurality of data sets 4 may be obtained as a result of an episode in reinforcement learning. Alternatively, the controller 11 may generate a plurality of new data sets from the result of the episode in reinforcement learning and adjust (optimize) the arithmetic parameters of the control model 5 using the generated plurality of new data sets and the plurality of data sets 4. In the deep reinforcement learning, for example, an arbitrary method such as recurrent replay distributed DON from demonstrations (R2D3) may be employed.

### (Specific Example of Event)

In the present embodiment, in the above-described machine learning, the controller 11 preferentially uses data sets for which reaction speed with respect to an event of the control commands indicated by the correct answer data 45 is evaluated as more appropriate as a result of the reaction speed matching a predetermined condition.

As described above, the event may include any event that can be involved with operation of the mobile object. Further, the event may include any event that can be detected by the sensor S. As one example, the mobile object (mobile object M) may be a vehicle, and the event may include at least one of deceleration of the preceding vehicle of the vehicle, cutting-in of a vehicle traveling side by side, occurrence of a parked vehicle, occurrence of an obstacle or change of a traffic light.

The predetermined condition may be specified as appropriate so as to evaluate appropriate reaction speed in accordance with the event. A start time point of the event may be specified by the sensor data obtained by the sensor S. The reaction speed may be defined by a time point from the start time point of the event until a start time point of operation control (operation) with respect to the event. Specific examples will be described below.

### (A) Deceleration of Preceding Vehicle

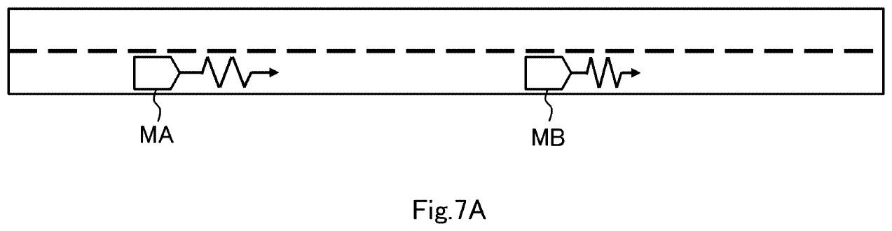

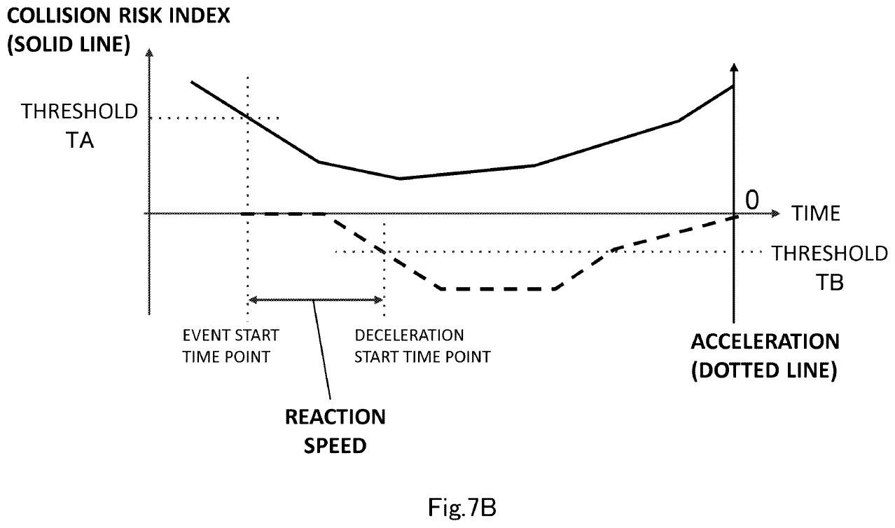

FIG. 7A schematically illustrates an example of the event (deceleration of the preceding vehicle). In the example in FIG. 7A, a vehicle MA is a vehicle that encounters the event. In other words, in a learning stage, it may be assumed that the data sets 4 are obtained from the vehicle MA. On the other hand, a vehicle MB is the preceding vehicle of the vehicle MA.

In a case where the vehicle MA encounters deceleration of the preceding vehicle MB, arbitrary operation for handling the deceleration of the preceding vehicle MB may be executed in the vehicle MA. One example of control operation that can be performed in the vehicle MA is deceleration operation in accordance with the preceding vehicle MB. Thus, in one example, the reaction speed may be defined by a period from a time point at which the preceding vehicle MB starts deceleration (a time point at which deceleration is detected) until a time point at which the vehicle MA starts deceleration operation.

Deceleration of the preceding vehicle MB can be detected by, for example, the sensor (sensor S) regarding speed, a position or a distance between vehicles, such as a camera, a radar and LiDAR. An index for detecting deceleration of the preceding vehicle MB may be specified as appropriate. In one example, as the index for detecting deceleration of the preceding vehicle MB, a collision risk index such as a time-to-collision (TTC) and a margin-to-collision (MTC) may be used.

On the other hand, deceleration operation in the vehicle MA may be detected using at least one of speed, an acceleration or a brake amount of the vehicle MA. As one example, a timing at which the deceleration operation is executed in the vehicle MA may be detected by threshold evaluation with respect to at least one of the speed, the acceleration or the brake amount of the vehicle MA.

Thus, in one example of the present embodiment, the reaction speed of deceleration operation with respect to deceleration of the preceding vehicle MB may be defined by a period from a time point at which the deceleration of the preceding vehicle MB is detected (start time point of the event) until a time point at which the deceleration operation of the vehicle MA is detected (start time point of the operation). The reaction speed is evaluated as higher as the period is shorter, and the reaction speed is evaluated as slower as the period is longer.

FIG. 7B schematically illustrates an example of a method for evaluating reaction speed of response operation in response to deceleration of the preceding vehicle. In the example in FIG. 7B, a collision risk index is employed as the index for detecting the deceleration of the preceding vehicle MB, and an acceleration (negative acceleration) of the vehicle MA is employed as the index for detecting the deceleration operation. A threshold TA is set for the collision risk index for detecting a start time point of the event (deceleration of the preceding vehicle MB), and a threshold TB is set for the acceleration of the vehicle MA for detecting a start time point of the deceleration operation. The threshold TB may be set in view of an external factor such as, for example, influence of a road surface. The respective thresholds (TA, TB) may be manually set by the operator or may be at least partially automatically set by a statistic. In the example in FIG. 7B, the reaction speed can be calculated from a period from an event start time point detected by the threshold TA (on the basis of the collision risk index) to a start time point of the deceleration operation detected by the threshold TB (on the basis of the acceleration of the vehicle MA).

Note that the operation (operation control) of the vehicle MA with respect to the preceding vehicle MB does not have to be limited to deceleration as in the example as described above and may be selected as appropriate in accordance with the embodiment. In another example, in a case where the vehicle MA encounters deceleration of the preceding vehicle MB, the vehicle MA may make a lane change. In this case, a start time point of operation of the lane change may be detected by at least one of speed, an acceleration, a brake amount, an acceleration amount or a steering amount of the vehicle MA, and the reaction speed may be calculated in accordance with the start time point. The steering amount may be measured by, for example, steering torque. In another example, the start time point of the operation of the lane change may be detected by vehicle operation such as operation of a direction indicator. Further, a signal of the preceding vehicle MB such as whether or not a stop lamp of the preceding vehicle MB is turned on may be used as an index for detecting deceleration of the preceding vehicle MB.

### (B) Cutting-In of Vehicle Traveling Side by Side

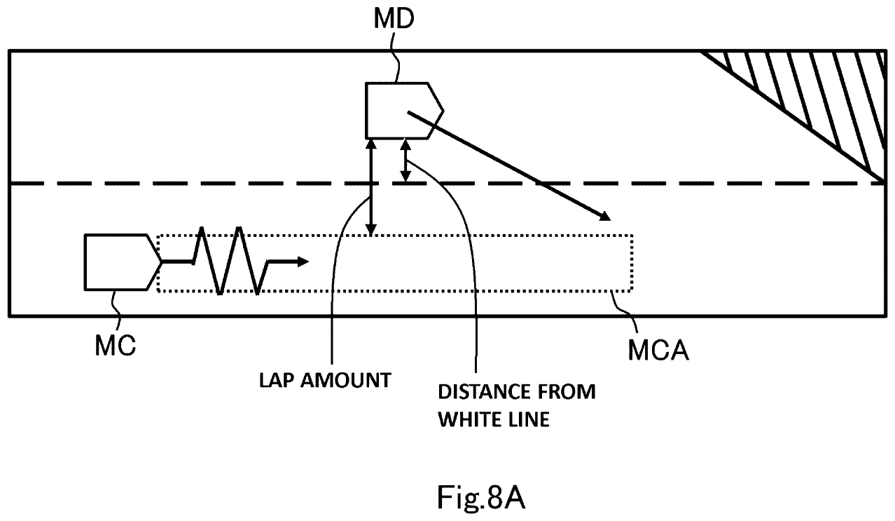

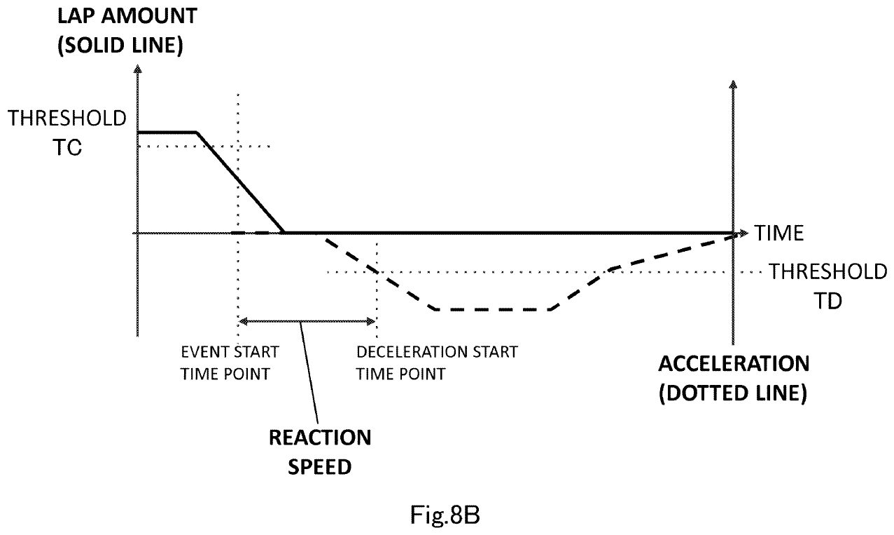

FIG. 8A schematically illustrates an example of the event (cutting-in of a vehicle traveling side by side). In the example in FIG. 8A, a vehicle MC is a vehicle that encounters the event. In other words, in a learning stage, it may be assumed that the data sets 4 are obtained from the vehicle MC. On the other hand, a vehicle MD is a vehicle traveling side by side of the vehicle MC. In the example in FIG. 8A, it is assumed that the vehicle MD traveling side by side cuts in ahead of the vehicle MC.

In a case where the vehicle MC encounters cutting-in of the vehicle MD traveling side by side, arbitrary operation for handling cutting-in of the vehicle MD traveling side by side may be executed in the vehicle MC. One example of control operation that can be performed in the vehicle MC is deceleration operation in accordance with cutting-in of the vehicle MD traveling side by side. Thus, in one example, the reaction speed may be defined by a period from a start time point (time point at which cutting-in is detected) at which the vehicle MD traveling side by side starts cutting-in until a time point at which the vehicle MC starts the deceleration operation.

Cutting-in of the vehicle MD traveling side by side can be detected by the sensor (sensor S) regarding speed, a position or a distance between vehicles, such as, for example, a camera, a radar and LiDAR. An index for detecting cutting-in of the vehicle MD traveling side by side may be specified as appropriate. In one example, as the index for detecting cutting-in of the vehicle MD traveling side by side, a distance index such as a lap amount and a distance between the vehicle MD traveling side by side and a white line may be used. For example, cutting-in of the vehicle MD traveling side by side may be detected by a timing at which the lap amount becomes equal to or less than a fixed value, a timing at which the vehicle MD traveling side by side reaches the white line, or the like. Note that the lap amount is a distance in a vehicle width direction (a horizontal direction with respect to a vehicle traveling direction, a vertical direction in the drawing) between another vehicle (vehicle MD traveling side by side) and a predicted course MCA of the own vehicle (vehicle MC). The predicted course MCA may be, for example, a course predicted range of the vehicle MC indicated with a dotted line in the drawing. On the other hand, in a similar manner to (A) described above, the deceleration operation in the vehicle MC may be detected by at least one of speed, an acceleration or a brake amount of the vehicle MC. Thus, in one example of the present embodiment, the reaction speed of the deceleration operation with respect to cutting-in of the vehicle MD traveling side by side may be defined by a period from a time point (start time point of the event) at which cutting-in of the vehicle MD traveling side by side is detected until a time point (start time point of the operation) at which the deceleration operation of the vehicle MC is detected.

FIG. 8B schematically illustrates an example of a method for evaluating the reaction speed of the response operation with respect to cutting-in of the vehicle traveling side by side. In the example in FIG. 8B, a lap amount is employed as an index for detecting cutting-in of the vehicle MD traveling side by side, and an acceleration (negative acceleration) of the vehicle MC is employed as an index for detecting the deceleration operation. A threshold TC is set for the lap amount to detect the start time point of the event (cutting-in of the vehicle MD traveling side by side), and a threshold TD is set for the acceleration of the vehicle MC to detect the start time point of the deceleration operation. The threshold TD may be set in view of an external factor such as, for example, influence of a road surface. The respective thresholds (TC, TD) may be manually set by the operator or may be at least partially automatically set by a statistic, or the like. In the example in FIG. 8B, the reaction speed can be calculated from a period from an event start time point detected by the threshold TC (on the basis of the lap amount) to a start time point of the deceleration operation detected by the threshold TD (on the basis of the acceleration of the vehicle MC).

Note that the operation (operation control) of the vehicle MC with respect to the vehicle MD traveling side by side does not have to be limited to deceleration as in the example as described above and may be selected as appropriate in accordance with the embodiment. In another example, in a case where the vehicle MC encounters cutting-in of the vehicle MD traveling side by side, the vehicle MC may make a lane change. In this case, the start time point of operation of the lane change may be detected by at least one of speed, an acceleration, a brake amount, an acceleration amount or a steering amount of the vehicle MC, and the reaction speed may be calculated in accordance with the start time point. In another example, the start time point of the operation of the lane change may be detected by vehicle operation such as operation of a directional indicator. Further, a signal of the vehicle MD traveling side by side such as whether or not a stop lamp of the vehicle MD traveling side by side is turned on and whether or not a turn-signal lamp is turned on may be used as an index for detecting cutting-in of the vehicle MD traveling side by side.

Further, an aspect of cutting-in of the vehicle MD traveling side by side can vary depending on scenes. In one example, cutting-in at a location where traveling is impossible such as a junction and a construction section, there is a possibility that the vehicle MC may be required to handle the cutting-in at an earlier timing than timings for other cases of cutting-in (for example, normal lane change) to allow the vehicle MD traveling side by side to certainly perform cutting-in. Thus, the events of cutting-in may be categorized in accordance with scenes.

### (C) Occurrence of Parked Vehicle

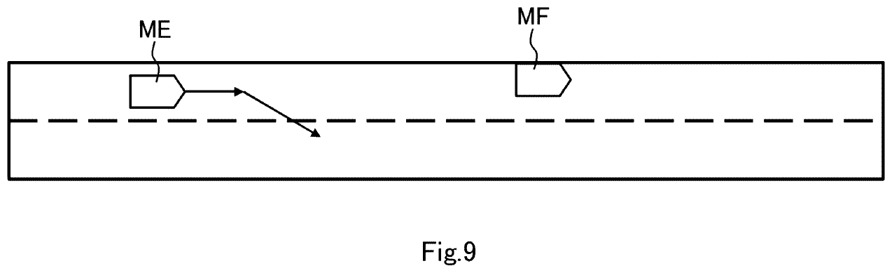

FIG. 9 schematically illustrates an example of the event (occurrence of the parked vehicle). In the example in FIG. 9, a vehicle ME is a vehicle that encounters the event. In other words, in a learning stage, it may be assumed that the data sets 4 are obtained from the vehicle ME. On the other hand, a vehicle MF is the parked vehicle. In the example in FIG. 9, it is assumed that the vehicle MF is parked ahead of the vehicle ME.

In a case where the vehicle ME encounters occurrence of the parked vehicle MF, arbitrary operation for handling the parked vehicle MF may be executed in the vehicle ME. In one example, occurrence of the parked vehicle MF may be dealt with in a similar manner to deceleration of the preceding vehicle MB in (A) described above by replacing the preceding vehicle MB with the parked vehicle MF. In other words, in one example, one example of the control operation that can be performed in the vehicle ME is deceleration or avoiding (such as lane change) operation in response to occurrence of the parked vehicle MF. The reaction speed may be defined by a period from a time point (time point at which the parked vehicle MF is detected) at which the parked vehicle MF occurs until a time point at which deceleration or avoiding operation is started in the vehicle ME.

Occurrence of the parked vehicle MF can be detected by the sensor (sensor S) regarding speed, a position, or a distance between vehicles, such as, for example, a camera, a radar, and LiDAR. In one example, the above-described collision risk index may be used as an index for detecting the parked vehicle MF. As the collision risk index for detecting the parked vehicle MF, an index such as a distance to the parked vehicle MF and a distance between vehicles/traveling speed (time head way (THW)) may be used in addition to the TTC and the MTC described above. Thus, in one example of the present embodiment, the reaction speed with respect to occurrence of the parked vehicle MF may be calculated by a period from an event start time point detected by threshold determination on the value of the collision risk index to a start time point of the operation detected by threshold determination on a value of an operation amount (at least one of speed, an acceleration, a brake amount, an acceleration amount, or a steering amount) of the vehicle ME. In another example, the start time point of the avoiding operation may be detected by vehicle operation such as operation of a directional indicator. Further, a signal of the parked vehicle MF such as whether or not hazard lights of the parked vehicle MF are turned on may be used as an index for detecting occurrence of the parked vehicle MF.

### (D) Occurrence of Obstacle

Occurrence of an obstacle is similar to occurrence of the parked vehicle MF described above. The reaction speed of the operation in response to occurrence of an obstacle can be evaluated in a similar manner to the reaction speed of the operation in response to occurrence of the parked vehicle MF described above by replacing the parked vehicle MF in the above-described example with an obstacle. In one example of the present embodiment, the reaction speed in response to occurrence of an obstacle may be calculated from a period from an event start time point detected by threshold determination on a value of the collision risk index until a start time point of the operation detected by threshold determination on a value of an operation amount of the vehicle. The collision risk index may be measured by replacing the above-described parked vehicle MF with an obstacle. In another example, the start time point of the avoiding operation may be detected by vehicle operation such as operation of a directional indicator. Note that as described above, the obstacle may be, for example, a pedestrian, a bicycle, or the like.

### (E) Change of Traffic Light

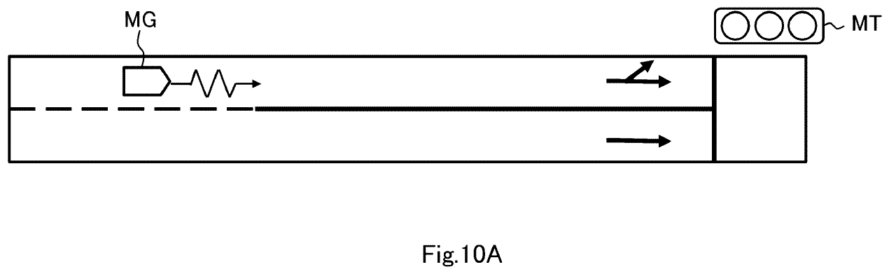

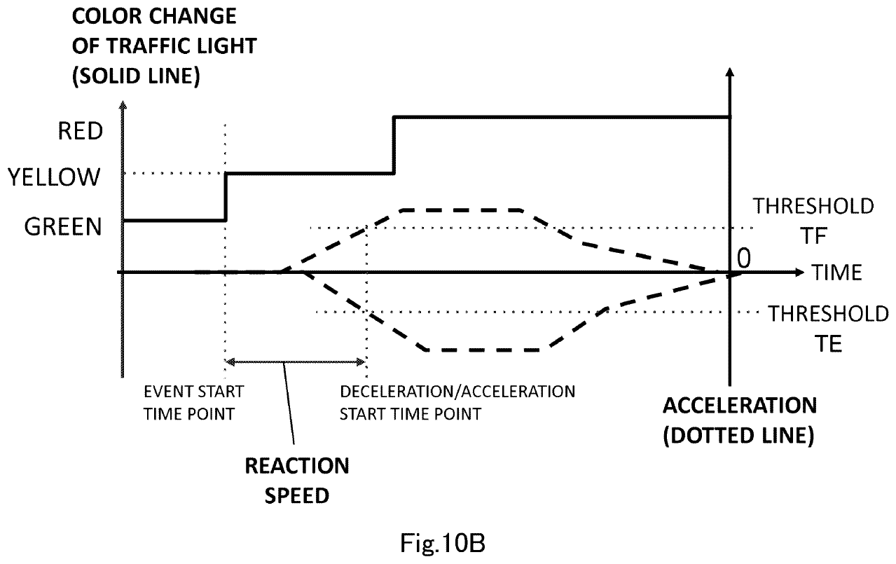

FIG. 10A schematically illustrates an example of the event (change of the traffic light). In the example in FIG. 10A, a vehicle MG is a vehicle that encounters the event. In other words, in a learning stage, it may be assumed that the data sets 4 are obtained from the vehicle MG.

In a case where the vehicle MG encounters change of a traffic light MT, arbitrary operation for handling change of the traffic light MT may be executed in the vehicle MG. As one example, in a case where the traffic light MT changes from a light allowing proceeding to a light for encouraging deceleration or a light for calling attention (from a green light to a yellow light), one example of the control operation that can be performed in the vehicle MG is deceleration operation for stopping before the traffic light MT or acceleration operation for passing through a road on which the traffic light MT is provided. Thus, in one example, the reaction speed may be defined by a period from a time point at which the traffic light MT starts change (time point at which change is detected) until a time point at which the vehicle MG starts deceleration or acceleration operation.

The change of the traffic light MT can be detected by the sensor (sensor S) such as, for example, a camera. A result of identifying color of the light of the traffic light MT may be used as an index for detecting change of the traffic light MT. The color of the light of the traffic light MT may be identified using an arbitrary method. On the other hand, the deceleration or acceleration operation in the vehicle MG may be detected by at least one of speed, an acceleration, an acceleration amount, or a brake amount of the vehicle MG. Thus, in one example of the present embodiment, the reaction speed of the deceleration or acceleration operation in response to change of the traffic light MT may be defined by a period from a time point (start time point of the event) at which change of the traffic light MT is detected until a time point (start time point of the operation) at which deceleration or acceleration operation of the vehicle MG is detected. Different thresholds may be set for the deceleration operation and the acceleration operation.

FIG. 10B schematically illustrates an example of a method for evaluating reaction speed of response operation in response to change of the traffic light. In the example in FIG. 10B, it is assumed that color of the light of the traffic light MT changes instantaneously. In the example in FIG. 10B, a result of identifying color of the light of the traffic light MT is employed as an index for detecting change of the traffic light MT, and an acceleration of the vehicle MG is employed as an index for detecting deceleration or acceleration operation. A threshold TE is set for the acceleration of the vehicle MG to detect a start time point of the deceleration operation, and a threshold TF is set for the acceleration of the vehicle MG to detect a start time point of the acceleration operation. The respective thresholds (TE, TF) may be set in view of an eternal factor such as, for example, influence of a road surface. The respective thresholds (TE, TF) may be manually set by the operator or may be at least partially automatically set by a statistic, or the like. In the example in FIG. 10B, the reaction speed of the deceleration operation can be calculated from a period from a time point (start time point of the event) at which the traffic light MT changes until a start time point of the deceleration operation detected by the threshold TE (on the basis of the acceleration of the vehicle MG). Further, the reaction speed of the acceleration operation can be calculated from a period from a time point (start time point of the event) at which the traffic light MT changes until a start time point of the acceleration operation detected by the threshold TF (on the basis of the acceleration of the vehicle MG).

Note that the event of the change of the traffic light MT does not have to be limited to the above-described example (change from a green light to a yellow light) and may be set as appropriate in accordance with the embodiment. In another example, in place of the timing at which the traffic light changes to a yellow light, a timing at which the traffic light changes to a red light may be detected as the start time point of the event of the change of the traffic light MT.

Further, in the above-described example, a timing at which change of the traffic light MT is completed (for example, a timing at which the state shifts from a state where the green light is turned on to a state where the green light is turned off, and the yellow light is turned on) is defined as a time point of change of the traffic light MT (start time point of the event). However, definition of the start time point of the event does not have to be limited to such an example and may be set as appropriate in accordance with the embodiment. In another example, the traffic light MT may include a traffic light for pedestrians other than a traffic light for vehicles (FIG. 10A illustrates an image of the traffic light for vehicles). In this case, an arbitrary timing from when the traffic light for pedestrians starts blinking until change of the traffic light for vehicles is completed may be defined as the time point of the change of the traffic light MT (start time point of the event).

### (Specific Example of Preferential Use)

The controller 11 preferentially uses data sets for which the reaction speed is evaluated as more appropriate in machine learning among the plurality of data sets 4. In other words, the controller 11 reflects data sets for which the reaction speed is evaluated as appropriate more in training of the control model 5 than data sets for which the reaction speed is not evaluated as appropriate. In the present embodiment, preferentially using the data sets may be performed using at least one of the following three methods.

### (1) First Method

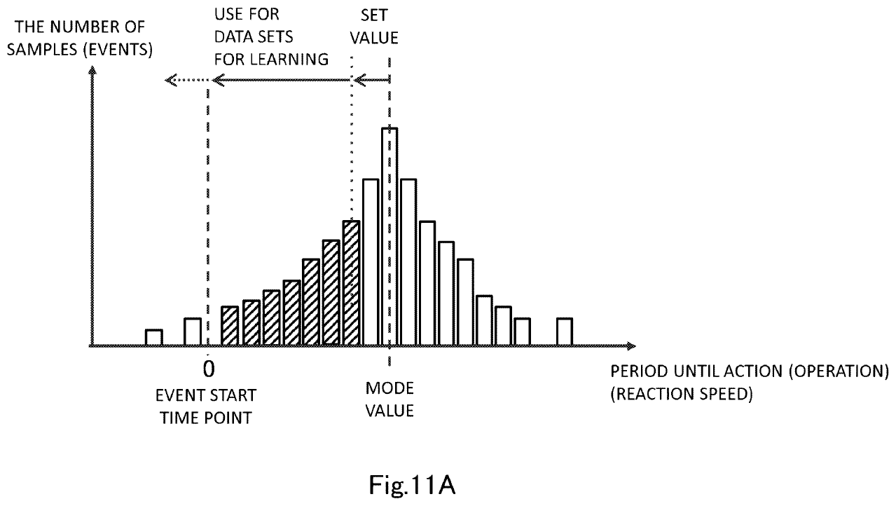

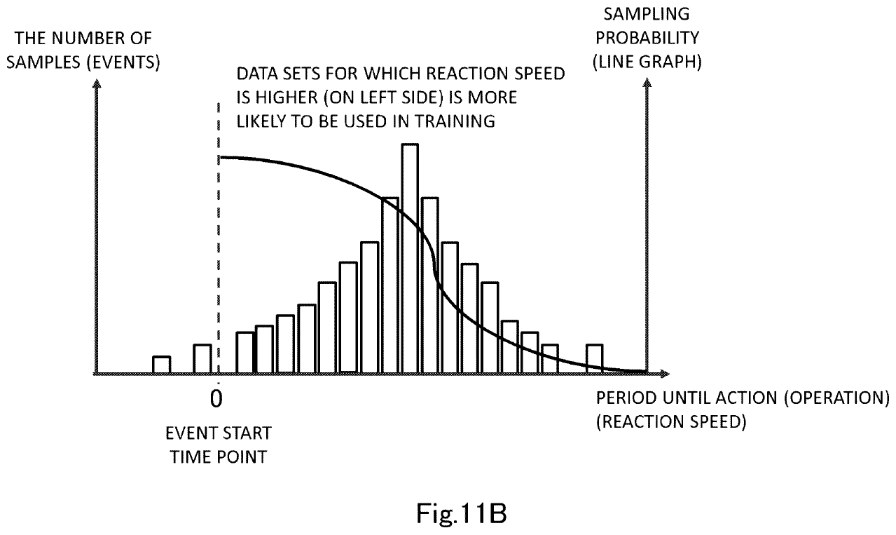

FIG. 11A schematically illustrates an example of a first method of preferentially using data sets for which the reaction speed is evaluated as more appropriate. As the first method, the controller 11 may perform control to use data sets for which the reaction speed is evaluated as appropriate in training of the control model 5 and not to use data sets for which the reaction speed is not evaluated as appropriate in training of the control model 5.

A graph in FIG. 11A represents the number of events (samples) with respect to the reaction speed in histogram. The number of events may be the number of data sets or may be tallied at least partially differently from collection of the data sets. Whether or not the reaction speed is appropriate may be evaluated by an arbitrary statistic. In one example, the statistic may be an average value, a mode value, an n-percentile value, or the like. n may be an arbitrary numerical value. The n-percentile value may be, for example, a 50-percentile value (median value), a 25-percentile value, or the like.

In one example, whether or not the reaction speed is appropriate (matches a predetermined condition) may be segmented by this statistic (corresponding to a case where the set value is 0 in the example in FIG. 11A). In a case where the reaction speed is evaluated as more appropriate as the reaction speed is higher, data sets for which the reaction speed is higher than the statistic that is a reference may be used in machine learning as data sets for which the reaction speed is appropriate. In other words, the controller 11 may use the statistic that is the reference as an upper limit value of the reaction speed. In a case where a range of appropriate reaction speed is specified, the upper limit value and the lower limit value may be set from corresponding statistics. As a specific example, in a case where it is assumed that the data sets are tallied starting from data sets for which the reaction speed is higher, the lower limit value of the reaction speed may be specified by the 25-percentile value, and the upper limit value of the reaction speed may be specified by a 75-percentile value.

In another example, the controller 11 may derive a reference value by executing arbitrary calculation on the statistic without using the statistic as it is as the reference. In simplicity, the controller 11 may derive the reference value by adding or subtracting a set value to or from the statistic. Then, whether or not the reaction speed is appropriate may be segmented by the derived reference value in place of the statistic described above. In other words, in a case where the reaction speed is evaluated as more appropriate as the reaction speed is higher, data sets for which the reaction speed is higher than the reference value may be used in machine learning as data sets for which the reaction speed is appropriate. In a case where a range of appropriate reaction speed is specified, the upper limit value and the lower limit value may be derived from the same statistic. Alternatively, the upper limit value and the lower limit value may be derived from different statistics. In each case, a magnitude of the set value for deriving the upper limit value may be the same as or different from a magnitude of the set value for deriving the lower limit value.

In the example in FIG. 11A, a mode value is employed as an evaluation index. The reference value is calculated by subtracting the set value from the reaction speed (a period from the event start time point to the operation start time point) of the mode value. Further, data sets for which the reaction speed is higher than the reference value are evaluated as data sets for which the reaction speed is appropriate (hatched range in FIG. 11A). In this first method, the controller 11 may exclude data sets for which the reaction speed is not evaluated as appropriate and execute the above-described processing of machine learning using only the data sets for which the reaction speed is evaluated as appropriate.

### (2) Second Method

FIG. 11B schematically illustrates an example of a second method of preferentially using data sets for which the reaction speed is evaluated as more appropriate. As the second method, the controller 11 may set a high sampling probability for the first data set for which the reaction speed is evaluated as appropriate among the plurality of data sets 4 and may set a low sampling probability for the second data set for which the reaction speed is not evaluated as appropriate. In other words, the controller 11 may increase the number of times of sampling in machine learning for data sets for which the reaction speed is evaluated as appropriate.

In one example, the sampling probability (the number of times) corresponds to a probability (the number of times) of data sets being extracted as a mini batch in the above-described machine learning. Thus, as the sampling probability is higher (as the number of times of sampling is larger), data sets are used in adjustment of values of the arithmetic parameters of the control model 5 more times. By this means, it is possible to reflect data sets for which the reaction speed is evaluated as appropriate more in training of the control model 5 than data sets for which the reaction speed is not evaluated as appropriate.

A method for setting the sampling probability (the number of times) in accordance with the reaction speed may be determined as appropriate in accordance with the embodiment. In one example, the controller 11 may determine the sampling probability (the number of times) of each data set 4 using a function expression designed as appropriate so that the sampling probability (the number of times) becomes higher as the reaction speed matches the predetermined condition.

Further, in the second method, the controller 11 may perform control to exclude (that is, make the sampling probability 0) at least part of the second data set for which the reaction speed is not evaluated as appropriate from a target of machine learning. Alternatively, the controller 11 may perform control not to exclude (that is, not to make the sampling probability 0) the second data set for which the reaction speed is not evaluated as appropriate from a target of machine learning.

In the example in FIG. 11B, the predetermined condition is specified so that the reaction speed is evaluated as more appropriate as the reaction speed is higher. In other words, the sampling probability is set higher for data sets for which the reaction speed is higher. Further, the second data set is not excluded from the target of machine learning. As a specific example, a sampling probability P (i) of a data set for which the reaction speed is the i-th highest among the plurality of data sets 4 may be specified by the following expression 1.

$$P ( i ) = \frac{{{p}_{i}}^{a}}{{\sum }_{k}^{N} {{p}_{k}}^{a}} , {p}_{i} = 1 / rank ( i ) \qquad ( Expression 1 )$$

a is a positive real number and may be arbitrarily set. rank (i) indicates rank order of the reaction speed. N indicates rank order of the lowest reaction speed. The controller 11 may generate a mini batch in accordance with the sampling probability P (i) specified by the above-described expression 1 and may execute the above-described processing of machine learning using the generated mini batch. Note that the function expression that specifies the sampling probability does not have to be limited to the example of the above-described expression 1 and may be designed as appropriate in accordance with the embodiment.

Further, as an optional measure, a weight of training of each data set 4 may be adjusted in accordance with the sampling probability. In one example, a case can occur where data sets with low sampling probabilities are not reflected in adjustment of the values of the arithmetic parameters of the control model 5 at all. To avoid this case, the weight of training may be made greater for data sets with lower sampling probabilities to a degree not to invalidate priority of the sampling probability. As described above, making the weight of training greater may be performed by increasing a learning rate. As a specific example, a weight wᵢ of training for a data set for which the reaction speed is the i-th highest may be calculated from the sampling probability P(i) using the following expression 2.

$${w}_{i} = ( \frac{1}{N} \cdot \frac{1}{P ( i )} ) \qquad ( Expression 2 )$$

Note that the function expression that specifies the weight of training of the data sets does not have to be limited to the example of the above-described expression 2 and may be designed as appropriate in accordance with the embodiment. In another example, the weight of training of the data sets may be specified without depending on the sampling probability.

### (3) Third Method

As a third method, the controller 11 may execute the above-described processing of machine learning after setting a greater weight of training for the first data set for which the reaction speed is evaluated as appropriate among the plurality of data sets 4 and setting a smaller weight of training for the second data set for which the reaction speed is not evaluated as appropriate.

In one example, the controller 11 may set a greater weight of training by increasing the learning rate in the above-described machine learning and may set a smaller weight of training by decreasing the learning rate. As a value of the learning rate becomes greater, an update amount becomes greater when the values of the arithmetic parameters of the control model 5 are adjusted in the fourth step of the above-described machine learning. This makes it possible to reflect data sets for which the reaction speed is evaluated as appropriate in training of the control model 5 more than data sets for which the reaction speed is not evaluated as appropriate.

A method for setting a weight of training in accordance with the reaction speed may be determined as appropriate in accordance with the embodiment. In one example, the controller 11 may determine the weight of training of each data set 4 using a function expression designed as appropriate to increase the weight of training as the reaction speed matches the predetermined condition.

Further, in the third method, the controller 11 may perform control to exclude (that is, make the weight of training 0) at least part of the second data set for which the reaction speed is not evaluated as appropriate from a target of machine learning. The data sets for which the weight of training is 0 may be made not to be used in machine learning. Alternatively, the controller 11 may perform control not to exclude (that is, not to make the weight of training 0) the second data set for which the reaction speed is not evaluated as appropriate from the target of machine learning.

Note that in the above-described first to third methods, extraction processing (calculation processing) of data sets to be preferentially used may be executed by arbitrary components. In one example, the extraction processing may be executed by the controller 11. In other words, the controller 11 may provide priority regarding use in machine learning to each data set 4 in accordance with the above-described first to third methods with reference to the reaction speed of each data set 4. In another example, the extraction processing may be implemented by a mechanism of a memory area that stores the data sets 4 without the controller 11 performing any processing. As a specific example, in a case where the data sets 4 are stored in a database, the extraction processing may be implemented as processing of the database. In other words, the controller 11 may extract each data set 4 from the database in a state where priority regarding use in machine learning is provided in accordance with the reaction speed (for example, a state where the data sets are sorted in order of the reaction speed on the database). Preventing the data sets from being used in the above-described machine learning may be performed by not extracting the data sets from the database. The controller 11 may perform machine learning in which data sets for which the reaction speed is evaluated as more appropriate are preferentially used by using the data sets extracted from the database as it is in machine learning. In the above-described third method, the controller 11 may set the weight of training in accordance with the extraction order (for example, in a case where the data sets are extracted starting from higher reaction speed, the controller 11 may set greater weights of training for data sets extracted earlier).

Further, in the above-described first to third methods, whether or not to use data sets for which start time points of operation are earlier than the event start time point (data sets located on a left side of the event start time point in FIG. 11A and FIG. 11B) in machine learning may be selected as appropriate in accordance with the embodiment.

The controller 11 may preferentially use data sets for which the reaction speed is evaluated as more appropriate in machine learning among the plurality of data sets 4 by employing at least one of the above-described first to third methods. The above-described first to third methods may be employed in combination. In the present embodiment, the controller 11 can generate the trained control model 5 by executing the processing of machine learning as described above. If machine learning of the control model 5 is completed, the processing of the controller 11 proceeds to the next step S103.

Note that the required operation can vary for each event. Thus, the controller 11 may generate the trained control model 5 for each event. Further, the plurality of data sets 4 to be acquired may include data sets regarding events other than the event for which priority is to be provided in accordance with the reaction speed. In this case, priority may be provided to data sets regarding other events using an arbitrary method. Alternatively, data sets regarding other events may be used in machine learning without priority being provided.

### <Step S103>

Returning to FIG. 6, in step S103, the controller 11 operates as the storage processing unit 113. In other words, the controller 11 generates information regarding the trained control model 5 generated through machine learning as the learning result data 125. The learning result data 125 may be constituted as appropriate so as to include information for regenerating the trained control model 5. The controller 11 stores the generated learning result data 125 in a predetermined memory area.

The predetermined memory area may be, for example, a RAM within the controller 11, the storage 12, an external main memory, a storage medium or a combination thereof. The storage medium may be, for example, a CD, a DVD, a semiconductor memory, or the like, and the controller 11 may store the learning result data 125 in the storage medium via the drive 16. The external main memory may be, for example, a data server such as a NAS. In this case, the controller 11 may store the learning result data 125 in the data server via a network by utilizing the communication interface 13. Further, the external main memory may be, for example, an external main memory. The external main memory may be connected to the model generation device 1 as appropriate. For example, the model generation device 1 may further include an external interface and may be connected to the external main memory via this external interface.

If storage of the result of machine learning is completed, the controller 11 finishes processing procedure of the model generation device 1 according to the present operation example.

Note that the generated learning result data 125 may be provided to the control device 2 at an arbitrary timing and using an arbitrary method. For example, the controller 11 may transfer the learning result data 125 to the control device 2 as the processing in the above-described step S103 or separately from the processing in step S103. The control device 2 may acquire the learning result data 125 by receiving this transferred data. Further, for example, the control device 2 may acquire the learning result data 125 by accessing the model generation device 1 or the data server via a network by utilizing the communication interface 23. Further, for example, the control device 2 may acquire the learning result data 125 via the storage medium 92. Still further, for example, the learning result data 125 may be incorporated into the control device 2 in advance.

Further, the controller 11 may update or newly generate the learning result data 125 by regularly or irregularly repeatedly executing the processing from step S101 to step S103 described above. When the processing is repeated, at least one or some of the data sets 4 to be used in machine learning may be changed, corrected, added, deleted, or the like, as appropriate. Further, the controller 11 may update the learning result data 125 held in the control device 2 by providing the updated or newly generated learning result data 125 to the control device 2 using an arbitrary method.

### [Control Device]

FIG. 12 is a flowchart indicating an example of processing procedure regarding automatic control of the target mobile object M using the trained control model 5 by the control device 2 according to the present embodiment. The following processing procedure is one example of a control method to be executed by a computer. However, the following processing procedure of the control device 2 is merely one example, and each step may be changed as far as possible. Further, concerning the following processing procedure, steps may be omitted, replaced, and added as appropriate in accordance with the embodiment.

### <Step S201>

In step S201, the controller 21 operates as the acquisition unit 211. In other words, the controller 21 acquires the target data 221 indicating environments in which the target mobile object M moves. In one example, the target data 221 may include the sensor data obtained by the sensor S. In addition, the target data 221 may include arbitrary information that can be involved with control, such as, for example, set speed, speed limit, map information and navigation information. The controller 21 may acquire various kinds of information using an arbitrary method. If the controller 21 acquires the target data 221, the processing proceeds to the next step S202.

### <Step S202>

In step S202, the controller 21 operates as the derivation unit 212. In other words, the controller 21 derives a control command from the acquired target data 221 using the trained control model 5.

Note that the controller 21 may set the trained control model 5 so as to be usable (that is, so as to be able to perform calculation processing) with reference to the learning result data 125 at an arbitrary timing before the processing in step S202 is executed. Further, in a case where the trained control model 5 is generated for each event, the controller 21 may specify an event that is encountered or likely to be encountered by the target mobile object M. Encounter of the event or its probability can be detected by the sensor S. The controller 21 may select the trained control model 5 corresponding to the specified event among a plurality of stored trained models 5. Then, the controller 21 may derive a control command from the acquired target data 221 using the selected trained control model 5.

The calculation processing of the trained control model 5 may be determined as appropriate in accordance with a type, a configuration, a structure, or the like, of the control model 5. In one example, in a case where the control model 5 is constituted with a neural network, the controller 21 inputs the target data 221 to the trained control model 5 and executes calculation processing of forward propagation of the trained control model 5. As a result of executing this calculation processing, the controller 21 can acquire an output value corresponding to a result of deriving the control command from the trained control model 5. In a case where an output of the control model 5 indirectly indicates the control command, the controller 21 may derive the control command by executing predetermined calculation processing on the output of the control model 5. If derivation of the control command is completed, the processing of the controller 21 proceeds to the next step S203.

### <Step S203>

In step S203, the controller 21 operates as the operation controller 213. In other words, the controller 21 controls operation of the target mobile object M in accordance with the result of deriving the control command. The controller 21 may directly or indirectly control the operation of the target mobile object M.

If control of the target mobile object M is completed, the controller 21 finishes the processing procedure of the control device 2 according to the present operation example. Note that the controller 21 may repeatedly execute a series of information processing from step S201 to step S203. A timing for repeating the processing may be determined as appropriate in accordance with the embodiment. In one example, the controller 21 may repeatedly execute a series of information processing from step S201 to step S203 during a predetermined period (for example, from when a power source of the mobile object M is activated until when the power source is stopped). This enables the control device 2 to continuously implement automatic control of the mobile object M.

### [Features]

In the present embodiment, the trained control model 5 is generated by preferentially using data sets for which reaction speed is evaluated as more appropriate in machine learning in the above-described processing in step S102. Capability of the trained model generated by machine learning depends on data sets to be used in the machine learning, and thus, according to the present embodiment, it can be expected to obtain the trained control model 5 that has obtained capability of implementing control of the mobile object at appropriate reaction speed. Further, by using such a trained control model 5 in the above-described processing in step S202, it can be expected to implement control of the target mobile object M at appropriate reaction speed.

### [4. Modifications]

While the embodiment of the present disclosure has been described above, the above description is merely an example of the present disclosure in all points. It goes without saying that various improvements or modifications can be made without deviating from the scope of the present disclosure. For example, the following changes can be made.

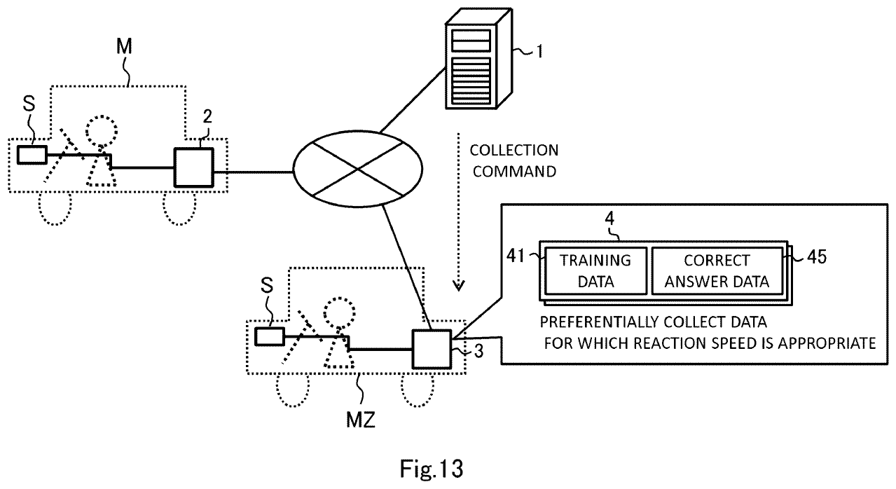

FIG. 13 schematically illustrates an example of another scene in which the present disclosure is applied. A system according to the modification includes a data collection device 3 in addition to the model generation device 1 and the control device 2 described above. The data collection device 3 is one or more computers configured to collect the data sets 4. In the present modification, the data collection device 3 collects a plurality of data sets 4 each including a combination of the training data 41 and the correct answer data 45. Collecting the plurality of data sets 4 may include preferentially collecting data sets for which reaction speed with respect to an event of control commands indicated by the correct answer data 45 is evaluated as more appropriate as a result of the reaction speed matching a predetermined condition. Further, the data collection device 3 outputs the collected plurality of data sets 4 to be used in machine learning.

In the example in FIG. 13, it is assumed that the data collection device 3 is mounted on a mobile object MZ and collects the data sets 4 in accordance with operation of the mobile object MZ by a subject. In one example, the data collection device 3 may generate the training data 41 from the sensor data obtained from the sensor S and other information (such as, for example, set speed, speed limit, map information and navigation information). Further, the data collection device 3 may generate the correct answer data 45 from a result of operation by the subject during a period while information constituting the training data 41 is obtained. Further, the data collection device 3 may acquire the data sets 4 by associating the generated training data 41 and the correct answer data 45. The data collection device 3 may be configured to execute processing of collecting the data sets 4 in accordance with a command from an external computer such as the model generation device 1. The devices 1 to 3 may exchange data with each other using an arbitrary method.

Note that a form of the data collection device 3 does not have to be limited to the example illustrated in FIG. 13. In another example, the data collection device 3 may be disposed separately from the mobile object MZ without being mounted on the mobile object MZ. Further, in another example, the data collection device 3 may be integrally constituted with the control device 2 or the model generation device 1. In other words, the control device 2 may also function as the data collection device 3 (in this case, the mobile object MZ is the mobile object M). Alternatively, the model generation device 1 may also function as the data collection device 3.

### [Hardware Configuration]

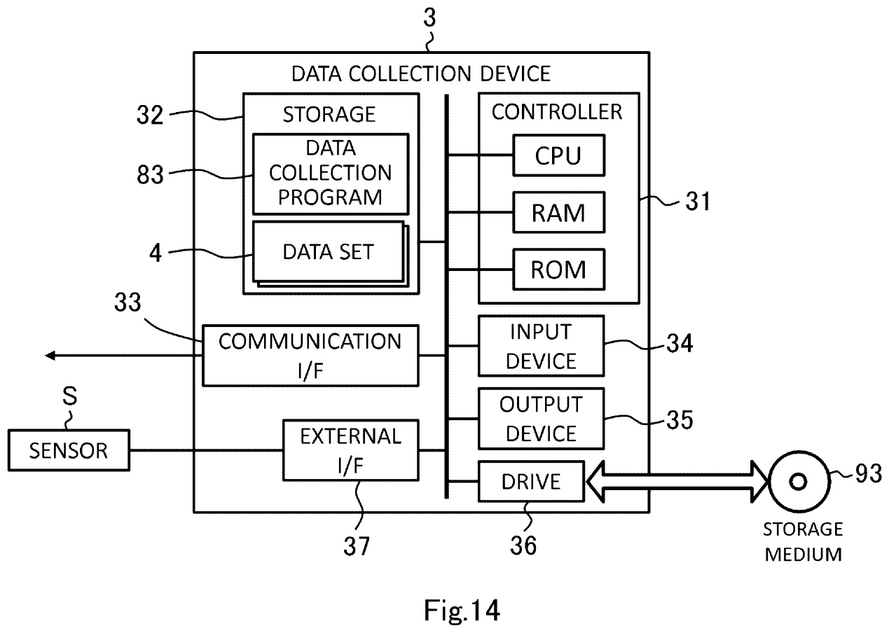

FIG. 14 schematically illustrates an example of a hardware configuration of the data collection device 3 according to the present modification. As illustrated in FIG. 14, the data collection device 3 according to the present modification is a computer to which a controller 31, a storage 32, a communication interface 33, an input device 34, an output device 35, a drive 36 and an external interface 37 are electrically connected.

The controller 31 to the external interface 37 of the data collection device 3 and the storage medium 93 may be respectively constituted in a similar manner to the controller 21 to the external interface 27 of the above-described control device 2 and the storage medium 92. The controller 31 (CPU) is one example of processor resources of the data collection device 3, and the storage 32 (and the RAM, the ROM) is one example of memory resources of the data collection device 3. In the present modification, the storage 32 stores various kinds of information such as the data collection program 83 and the data sets 4.

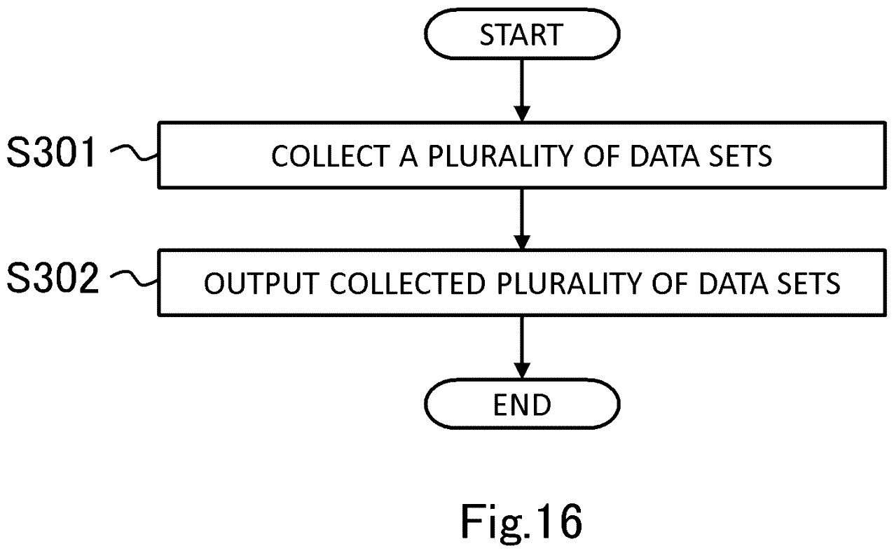

The data collection program 83 is a program for causing the data collection device 3 to execute information processing (FIG. 16 which will be described later) regarding collection of the data sets 4. The data collection program 83 includes a series of commands of the information processing. The data sets 4 may be accumulated as execution results of the data collection program 83. At least one of the data collection program 83 or the data sets 4 may be stored in the storage medium 93 in place of the storage 32 or in addition to the storage 32. The data collection device 3 may acquire the data collection program 83 from the storage medium 93.

The data collection device 3 may execute data communication with other computers (for example, the model generation device 1) via the communication interface 33. The operator (for example, the subject) can operate the data collection device 3 by utilizing the input device 34 and the output device 35. The input device 34 and the output device 35 may be integrally constituted by, for example, a touch panel display, or the like. The data collection device 3 may be connected to the sensor S via the external interface 37. However, a connection method of the sensor S does not have to be limited to such an example. In another example, the data collection device 3 may be connected to the sensor S via the communication interface 23.

Note that concerning a specific hardware configuration of the data collection device 3, components can be omitted, replaced, and added as appropriate in accordance with the embodiment. For example, the controller 31 may include a plurality of hardware processors. The hardware processors may include a microprocessor, an FPGA, a DSP, an ECU, a GPU, and the like. At least one of the communication interface 33, the input device 34, the output device 35, the drive 36, or the external interface 37 may be omitted. The data collection device 3 may be constituted with a plurality of computers. In this case, hardware configurations of the respective computers may be the same or do not have to be the same. The data collection device 3 may be general-purpose server device, a general-purpose computer, a mobile phone including a smartphone, a tablet personal computer (PC), or the like, other than a computer designed exclusively for a service to be provided. In a case where the mobile object MZ is a vehicle, the data collection device 3 may be an in-vehicle device.

### [Software Configuration]

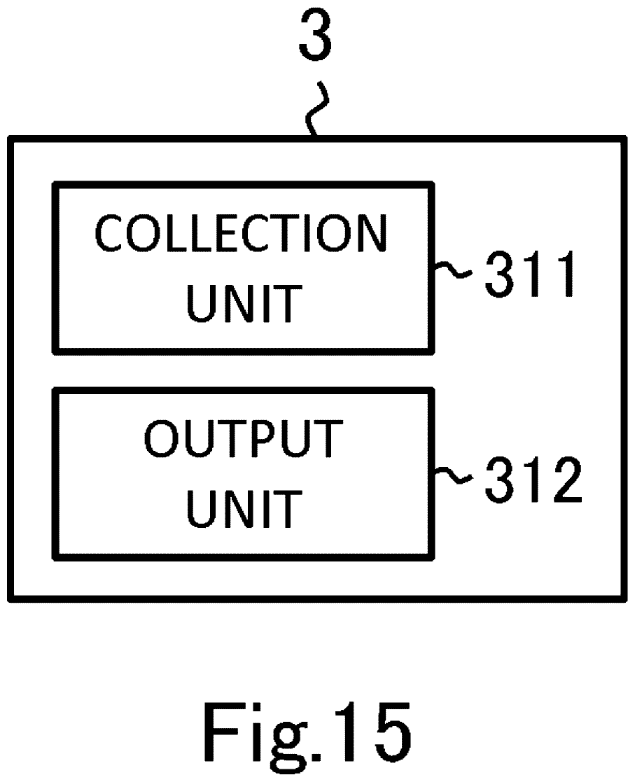

FIG. 15 schematically illustrates an example of a software configuration of the data collection device 3 according to the present embodiment. The controller 31 of the data collection device 3 loads the data collection program 83 stored in the storage 32 to the RAM and executes a command included in the data collection program 83 by the CPU. By this means, as illustrated in FIG. 15, the data collection device 3 according to the present embodiment operates as a computer including a collection unit 311 and an output unit 312 as software modules.

The collection unit 311 is configured to collect a plurality of data sets 4 each including a combination of the training data 41 and the correct answer data 45. Collecting the plurality of data sets 4 by the collection unit 311 may include preferentially collecting data sets for which reaction speed with respect to an event of control commands indicated by the correct answer data 45 is evaluated as more appropriate as a result of the reaction speed matching a predetermined condition. The output unit 312 is configured to output the collected plurality of data sets 4 to be used in machine learning.

Note that in the present modification, each software module of the data collection device 3 is implemented by the controller 31 (CPU) in a similar manner to the model generation device 1 and the control device 2 described above. In other words, an example where each software module of the data collection device 3 is implemented by a general-purpose CPU is described. However, part or all of the software modules of the data collection device 3 may be implemented by one or more dedicated processors. The above-described modules may be implemented as hardware modules. Concerning a software configuration of the data collection device 3, modules may be omitted, replaced and added as appropriate in accordance with the embodiment.

### [Operation Example]

FIG. 16 is a flowchart indicating an example of processing procedure regarding collection of the data sets 4 by the data collection device 3 according to the present modification. The following processing procedure is one example of a data collection method to be executed by a computer. However, the following processing procedure is merely one example, and each step may be changed as far as possible. Further, concerning the following processing procedure, steps may be omitted, replaced and added as appropriate in accordance with the embodiment.

### (Step S301)

In step S301, the controller 31 operates as the collection unit 311 and collects a plurality of data sets 4 each including a combination of the training data 41 and the correct answer data 45. In this event, in one example, the controller 31 may collect the data sets 4 regardless of whether or not the reaction speed is appropriate. In another example, the controller 31 may preferentially collect data sets for which reaction speed with respect to an event of control commands indicated by the correct answer data 45 is evaluated as more appropriate as a result of the reaction speed matching a predetermined condition.

Collecting the data sets 4 may be newly obtaining data sets or selecting data sets from data sets that have already been obtained. Newly obtaining data sets may be generating new data sets or obtaining data sets from other computers. Preferential collection may be executed in at least one of a stage of newly obtaining data sets or a stage of selecting data sets from the data sets that have already been obtained. Note that the stage of newly obtaining data sets can correspond to a first entry stage of storing data.

Preferential collection may be performed by increasing an amount of data sets for which reaction speed is evaluated as appropriate and reducing an amount of data sets for which reaction speed is not evaluated as appropriate. In one example, reducing the amount of data sets for which reaction speed is not evaluated as appropriate may include not collecting at least one or some of data sets regarding reaction speed among reaction speed not evaluated as appropriate.

In a case where a device that obtains data sets (first device) and a device that stores the obtained data sets (second device) are separately provided, preferential collection may be executed in one of the following three stages.
(1) Whether or not to continue to hold target data sets in a storage of the first device
(2) Whether or not to transmit (transfer) the target data sets from the first device to the second device
(3) Whether or not to continue to hold the target data sets in a storage of the second device

Note that one example of the first device is a terminal device (such as a user terminal and an in-vehicle device), and one example of the second device is a server device. The data collection device 3 may be either the first device or the second device. In the example in FIG. 13, it is assumed that the data collection device 3 is the first device.

In one example, the data collection device 3 may be the first device or the second device and may execute preferential collection in the above-described stage (1) or (3). In this case, preferentially collecting data sets for which reaction speed is evaluated as more appropriate may comprise, among data sets temporarily stored in a memory area (such as the RAM, the storage 32 and the storage medium 93) of the data collection device 3, maintaining data sets for which the reaction speed is evaluated as appropriate by the predetermined condition and deleting data sets for which the reaction speed is evaluated as not appropriate by the predetermined condition. By this means, the memory area of the data collection device 3 can be efficiently used in collection of appropriate data sets by not maintaining data sets for which the reaction speed is evaluated as not appropriate.

In another example, the data collection device 3 may be the first device and may execute preferential collection in the above-described stage (2). In this case, the second device is, for example, an external main memory such as an external server. In one example, the external server may be the model generation device 1 or a network server (such as a NAS). Transmission processing is executed in step S302 which will be described later. Thus, in a case where this form is employed, in the present step S301, the controller 31 may evaluate reaction speed of the obtained data sets to determine whether or not to perform transmission. In other words, preferential collection may include evaluating the reaction speed.

Note that the data sets 4 may be obtained using an arbitrary method. As described above, the data sets 4 may be obtained through operation of the mobile object MZ by the subject. The operation of the mobile object MZ may include override operation with respect to arbitrary automatic control other than complete manual operation. In addition, the data sets 4 may be obtained using a method such as simulation and data augmentation. If the plurality of data sets 4 are obtained, the processing of the controller 31 proceeds to the next step S302.

### (Step S302)

In step S302, the controller 31 operates as the output unit 312. In other words, the controller 31 outputs the collected plurality of data sets 4 so as to be used in machine learning.

Outputting the data sets so as to be used in machine learning may hold the collected plurality of data sets 4 in a distinguishable (identifiable) state so as to be able to be used in machine learning. Thus, outputting the collected plurality of data sets 4 may be performed by holding the collected plurality of data sets 4 in an arbitrary memory area. The arbitrary memory area may be a RAM, the storage 32, an external main memory, or the like. The external main memory may include the model generation device 1 and an external server such as a network server (such as a NAS).

In one example, the controller 31 may transmit the plurality of data sets 4 to the model generation device 1 via a network. The model generation device 1 may generate the trained control model 5 by executing the processing in step S102 and step S103 described above correspondingly. Note that in a case where the data collection device 3 is integrally constituted with the model generation device 1, collecting the data sets 4 in step S301 described above may be reflected in acquisition of data sets of a designated batch size in step S101 described above or machine learning. In this case, outputting processing in step S302 may be included in step S102 described above.

In another example, as described above, the data collection device 3 may reflect preferential collection in the above-described stage (2). In this case, outputting a plurality of data sets 4 may be performed by transmitting data sets for which the reaction speed is evaluated as appropriate by the predetermined condition to the second device and omitting transmission of data sets for which the reaction speed is evaluated as not appropriate by the predetermined condition to the second device. In one example, the second device may be the model generation device 1 or an external server such as a network server. This can reduce communication cost required for outputting the data sets 4 by omitting communication processing of data sets for which the reaction speed is evaluated as not appropriate.

If outputting of the plurality of data sets 4 is completed, the controller 31 finishes the processing procedure of the data collection device 3 according to the present operation example. Note that the controller 31 may repeatedly execute a series of information processing from step S301 to step S302. A timing for repeating the information processing may be determined as appropriate in accordance with the embodiment. In a typical example, the controller 31 may start execution of the above-described processing in step S301 in response to a data collection command from an external computer such as the model generation device 1. Then, until a collection stop command is received from the external computer, the controller 31 may repeatedly execute a series of information processing from step S301 to step S302. By this means, the data collection device 3 is configured to continuously collect the data sets 4 while a data collection instruction is provided.

### (Features)

In the present modification, the data collection device 3 preferentially collects data sets for which reaction speed is evaluated as more appropriate in the processing in step S301. By this means, data sets for which the reaction speed is evaluated as more appropriate can be preferentially used in machine learning in the processing in step S302 and subsequent processing. Thus, also according to the present modification, it can be expected to obtain the trained machine learning model (control model 5) that has obtained capability of implementing control of the mobile object at appropriate

### [5. Supplementary Note]

The processing and means described in the present disclosure can be freely combined and implemented unless technical inconsistency occurs.

Further, the processing described as being performed by one device may be executed by being shared by a plurality of devices. Alternatively, the processing described as being performed by different devices may be executed by one device. In a computer system, what kind of hardware configurations implements each function can be flexibly changed.

The present disclosure can be implemented by supplying a computer program that mounts functions described in the above-described embodiment to a computer, and one or more processors of the computer reading out and executing the program. Such a computer program may be provided to the computer by a non-transitory computer-readable storage medium that can be connected to a system bus of the computer or may be provided to the computer via a network. The non-transitory computer-readable storage medium includes, for example, an arbitrary type of disk such as a magnetic disk (such as a floppy (registered trademark) disk, and a hard disk drive (HDD)) and an optical disk (such as a CD-ROM, a DVD disk and a blue-ray disk) and an arbitrary type of medium appropriate for storing an electronic command, such as a read only memory (ROM), a random access memory (RAM), an EPROM, an EEPROM, a magnetic card, a flash memory, an optical card, and a semiconductor drive (such as a solid state drive).

What is claimed is:

1. A model generation method to be executed by a computer, the model generation method comprising:
acquiring a plurality of data sets each including a combination of training data indicating environments in which a mobile object moves in chronological order and correct answer data indicating control commands for the mobile object in the environments in chronological order; and
performing machine learning of a control model using the acquired plurality of data sets,
wherein performing the machine learning includes training the control model so that a result of deriving a control command of the mobile object from the training data using the control model matches the correct answer data for each of the data sets, and
using the plurality of data sets includes preferentially using data sets for which reaction speed with respect to an event of the control commands indicated by the correct answer data is evaluated as more appropriate as a result of the reaction speed matching a predetermined condition.

2. The model generation method according to claim 1,
wherein preferentially using the data sets for which the reaction speed is evaluated as more appropriate is performed by
increasing a sampling probability in the machine learning of a first data set for which the reaction speed is evaluated as appropriate among the plurality of data sets, and
decreasing a sampling probability in the machine learning of a second data set for which the reaction speed is not evaluated as appropriate than the sampling probability of the first data set without excluding the second data set from a target of the machine learning.

3. The model generation method according to claim 1,
wherein the mobile object includes a sensor,
the training data includes sensor data obtained by the sensor, and
a start time point of the event in the training data is specified by the sensor data.

4. The model generation method according to claim 1,
wherein the mobile object is a vehicle.

5. The model generation method according to claim 4,
wherein the event includes at least one of deceleration of a preceding vehicle, cutting-in of a vehicle traveling side by side, occurrence of a parked vehicle, occurrence of an obstacle, or change of a traffic light.

6. The model generation method according to claim 4,
wherein the control command includes at least one of acceleration, deceleration or steering of the vehicle.

7. A data collection method to be executed by a computer, the data collection method comprising:
collecting a plurality of data sets each including a combination of training data indicating environments in which a mobile object moves in chronological order and correct answer data indicating control commands for the mobile object in the environments in chronological order; and
outputting the collected plurality of data sets so as to be used in machine learning,
wherein collecting the plurality of data sets includes preferentially collecting data sets for which reaction speed with respect to an event of the control commands indicated by the correct answer data is evaluated as more appropriate as a result of the reaction speed matching a predetermined condition.

8. The data collection method according to claim 7,
wherein preferentially collecting the data sets for which the reaction speed is evaluated as more appropriate comprises, among data sets temporarily stored in a memory area of the computer, maintaining data sets for which the reaction speed is evaluated as appropriate by the predetermined condition and deleting data sets for which the reaction speed is evaluated as not appropriate by the predetermined condition.

9. The data collection method according to claim 7,
wherein outputting the plurality of data sets is performed by
transmitting data sets for which the reaction speed is evaluated as appropriate by the predetermined condition to an external server, and
omitting transmission of data sets for which the reaction speed is evaluated as not appropriate by the predetermined condition to the external server.

10. A non-transitory storage medium storing a control program for causing a computer to execute:
acquiring target data indicating environments in which a target mobile object moves;
deriving a control command from the acquired target data using a trained control model; and
controlling operation of the target mobile object in accordance with a result of deriving the control command,
wherein the trained control model is generated by performing machine learning using a plurality of data sets each including a combination of training data indicating environments in which a mobile object for training moves in chronological order and correct answer data indicating control commands for the mobile object for training in the environments in chronological order,
performing the machine learning includes training the control model so that a result of deriving the control command of the mobile object from the training data using the control model matches the correct answer data for each of the data sets, and
using the plurality of data sets in the machine learning includes preferentially using in the machine learning, data sets for which reaction speed with respect to an event of the control commands indicated by the correct answer data is evaluated as more appropriate as a result of the reaction speed matching a predetermined condition.

11. The non-transitory storage medium according to claim 10,
wherein the target mobile object is a vehicle.

12. The non-transitory storage medium according to claim 11,
wherein the event includes at least one of deceleration of a preceding vehicle, cutting-in of a vehicle traveling side by side, occurrence of a parked vehicle, occurrence of an obstacle or change of a traffic light.

13. The non-transitory storage medium according to claim 11,
wherein the control commands include at least one of acceleration, deceleration or steering of the vehicle.
